(19) United States
(12) Patent Application Publication
(10) Pub. No.: US 2010/0190334 A1
(43) Pub. Date: Jul. 29, 2010

(54) THREE-DIMENSIONAL SEMICONDUCTOR STRUCTURE AND METHOD OF MANUFACTURING THE SAME

(76) Inventor: Sang-Yun Lee, Beaverton, OR (US)

Correspondence Address: SCHMEISER OLSEN & WATTS, 18 E UNIVERSITY DRIVE, SUITE # 101, MESA, AZ, 85201, US

(21) Appl. No.: 12/731,087

(22) Filed: Mar. 24, 2010

Related U.S. Application Data
(63) Continuation-in-part of application No. 12/040,642, filed on Feb. 29, 2008.
Application No. 12/040,642 is a continuation-in-part of application No. 11/092,498, filed on Mar. 29, 2005, now Pat. No. 7,470,142.
Application No. 11/092,498 is a continuation-in-part of application No. 11/092,499, filed on Mar. 29, 2005, now Pat. No. 7,470,598.
Application No. 11/092,499 is a continuation-in-part of application No. 11/092,500, filed on Mar. 29, 2005.
Application No. 11/092,500 is a continuation-in-part of application No. 11/092,501, filed on Mar. 29, 2005.
Application No. 11/092,501 is a continuation-in-part of application No. 11/092,521, filed on Mar. 29, 2005, now Pat. No. 7,633,162.
Application No. 11/092,521 is a continuation-in-part of application No. 11/180,286, filed on Jul. 12, 2005.
Application No. 11/180,286 is a continuation-in-part of application No. 11/378,059, filed on Mar. 17, 2006.
Application No. 11/378,059 is a continuation-in-part of application No. 11/606,523, filed on Nov. 30, 2006.
Application No. 11/606,523 is a continuation-in-part of application No. 10/873,969, filed on Jun. 21, 2004, now Pat. No. 7,052,941.
Application No. 10/873,969 is a continuation-in-part of application No. 11/873,719, filed on Oct. 17, 2007.
Application No. 11/873,719 is a continuation-in-part of application No. 11/873,851, filed on Oct. 17, 2007, now Pat. No. 7,718,508.
Application No. 11/873,851 is a continuation-in-part of application No. 11/873,769, filed on Oct. 17, 2007.
Application No. 11/873,769 is a continuation-in-part of application No. 12/475,294, filed on May 29, 2009.
Application No. 12/475,294 is a continuation of application No. 12/470,344, filed on May 21, 2009.
Application No. 12/470,344 is a continuation-in-part of application No. 12/397,309, filed on Mar. 3, 2009.
Application No. 12/397,309 is a continuation-in-part of application No. 12/165,475, filed on Jun. 30, 2008.
Application No. 12/165,475 is a continuation-in-part of application No. 12/040,642, filed on Feb. 29, 2008.
Application No. 12/040,642 is a continuation-in-part of application No. 12/165,445, filed on Jun. 30, 2008, now Pat. No. 7,671,371.

(30) Foreign Application Priority Data
Jun. 24, 2003 (KR) 10-2003-0040920
Jul. 12, 2003 (KR) 10-2003-0047515
Mar. 3, 2008 (KR) 10-2004-0042830
May 21, 2008 (KR) 10-2008-0046991
May 30, 2008 (KR) 10-2008-50946
Dec. 5, 2008 (KR) 10-2008-0100892
Dec. 5, 2008 (KR) 10-2008-0100893
Dec. 5, 2008 (KR) 2008-123595
Mar. 24, 2009 (KR) 10-2009-24793

(51) Int. Cl. H01L 21/768

(52) U.S. Cl. 438/637; 257/E21.583

(57) ABSTRACT

A semiconductor circuit structure includes a support substrate which carries an interconnect region and electronic circuitry. The semiconductor circuit structure includes a device substrate coupled to the interconnect region through a conductive bonding layer. The device substrate includes a planarized surface which faces the conductive bonding layer. The device substrate can carry laterally oriented semiconductor devices which are connected to the electronic circuitry carried by the support substrate. The device substrate can be processed to form vertically oriented semiconductor devices which are connected, through the interconnect region and conductive bonding layer, to the electronic circuitry carried by the support substrate.

### CROSS-REFERENCE TO RELATED APPLICATIONS

This patent application claims priority to Korean Patent Application No. 10-2009-24793, which was filed on Mar. 24, 2009 by the same inventor, the contents of which are incorporated by reference as though fully set forth herein.

This application is a continuation-in-part of, and claims the benefit of, U.S. patent application Ser. Nos.:

12/475,294, filed on Mar. 29, 2009;

12/470,374, filed on Mar. 21, 2009;

12/397,309, filed on Mar. 3, 2009;

12/040,642, filed on Feb. 29, 2008,

11/092,498, filed on Mar. 29, 2005,

11/092,499, filed on Mar. 29, 2005,

11/092,500, filed on Mar. 29, 2005,

11/092,501, filed on Mar. 29, 2005;

11/092,521, filed on Mar. 29, 2005;

11/180,286, filed on Jul. 12, 2005;

11/378,059, filed on Mar. 17, 2006; and

11/606,523, filed on Nov. 30, 2006;

which in turn are continuation-in-parts of, and claim the benefit of, U.S. patent application Ser. No. 10/873,969 (now U.S. Pat. No. 7,052,941), filed on Jun. 21, 2004, which claims the benefit of Republic of Korea Patent Application Nos. 10-2003-0040920 and 10-2003-0047515, filed on Jun. 24, 2003 and Jul. 12, 2003, respectively, the contents of all of which are incorporated herein by reference in their entirety.

This is also a continuation-in-part of, and claims the benefit of, U.S. patent application Ser. Nos.:

11/873,719, filed on Oct. 17, 2007; and

11/873,851, filed on Oct. 17, 2007;

which in turn are divisionals of, and claim the benefit of, U.S. patent application Ser. No. 10/092,521, which is a continuation-in-part of, and claims the benefit of, U.S. patent application Ser. No. 10/873,969 (now U.S. Pat. No. 7,052,941), filed on Jun. 21, 2004, which claims the benefit of Republic of Korea Patent Application Nos. 10-2003-0040920 and 10-2003-0047515, filed on Jun. 24, 2003 and Jul. 12, 2003, respectively, the contents of both of which are incorporated herein by reference in their entirety.

This is also a continuation-in-part of, and claims the benefit of, U.S. patent application Ser. No. 11/873,769, filed on Oct. 17, 2007, which in turn is a divisional of, and claims the benefit of, U.S. patent application Ser. No. 10/092,500, which is a continuation-in-part of, and claims the benefit of, U.S. patent application Ser. No. 10/873,969 (now U.S. Pat. No. 7,052,941), filed on Jun. 21, 2004, which claims the benefit of Republic of Korea Patent Application Nos. 10-2003-0040920 and 10-2003-0047515, filed on Jun. 24, 2003 and Jul. 12, 2003, respectively, the contents of both of which are incorporated herein by reference in their entirety.

### BACKGROUND OF THE INVENTION

1. Field of the Invention

This invention relates to semiconductor materials and devices.

2. Description of the Related Art

Advances in semiconductor manufacturing technology have provided computer systems with integrated circuits that include many millions of active and passive electronic devices, along with the interconnects to provide the desired circuit connections. A typical computer system includes a computer chip, with processor and control circuits, and an external memory chip. As is well-known, most integrated circuits include laterally oriented active and passive electronic devices that are carried on a single major surface of a substrate. The current flow through laterally oriented devices is generally parallel to the single major surface of the substrate. Active devices typically include transistors and passive devices typically include resistors, capacitors and inductors. However, these laterally oriented devices consume significant amounts of chip area. Laterally oriented devices are sometimes referred to as planar or horizontal devices. Examples of laterally oriented devices can be found in U.S. Pat. Nos. 6,600,173 to Tiwari, 6,222,251 to Holloway and 6,331,468 to Aronowitz.

Vertically oriented devices extend in a direction that is generally perpendicular to the single major surface of the substrate. The current flow through vertically oriented devices is perpendicular to the single major surface of the substrate. Hence, the current flow through a vertically oriented semiconductor device is perpendicular to the current flow through a horizontally oriented semiconductor device. Examples of vertically oriented semiconductor device can be found in U.S. Pat. Nos. 5,106,775 to Kaga, 6,229,161 to Nemati and 7,078,739 to Nemati.

It should be noted that U.S. Pat. Nos. 5,554,870 to Fitch, 6,229,161 to Nemati and 7,078,739 to Nemati disclose the formation of both horizontal and vertical semiconductor devices on a single major surface of a substrate. However, forming both horizontal and vertical semiconductor devices on a single major surface of a substrate complicates the processing steps because the required masks and processing steps are not compatible.

Some references disclose forming an electronic device, such as a dynamic random access memory (DRAM) capacitor, by crystallizing polycrystalline and/or amorphous semiconductor material using a laser. One such electronic device is described in U.S. patent Application No. 20040156233 to Bhattacharyya. The laser is used to heat the polycrystalline or amorphous semiconductor material to form a single crystalline semiconductor material. However, a disadvantage of this method is that the laser is capable of driving the temperature of the semiconductor material to be greater than 800 degrees Celsius (° C.). In some situations, the temperature of the semiconductor material is driven to be greater than about 1000° C. It should be noted that some of this heat undesirably flows to other regions of the semiconductor structure proximate to the DRAM capacitor, which can cause damage.

Another type of semiconductor memory is referred to as a static random access memory (SRAM) circuit. There are many different circuits that operate as SRAM memory circuits, with examples being disclosed in U.S. Pat. Nos. 5,047,979, 5,265,047 and 6,259,623. Some SRAM memory circuits include four transistors per unit cell, and others include six transistors per unit cell. In general, an SRAM memory circuit occupies more area as the number of transistors it includes increases. Hence, an SRAM memory circuit having six transistors generally occupies more area than an SRAM memory circuit having four transistors.

The transistors of many SRAM memory circuits are metal oxide field effect (MOSFET) transistors, which can be n-channel or p-channel. An n-channel MOSFET is typically referred to as an NMOS transistor and a p-channel MOSFET is typically referred to as a PMOS transistor. SRAM memory circuits are complementary metal oxide semiconductor (CMOS) circuits when they include NMOS and PMOS transistors connected together. A substrate which carries a CMOS circuit requires a p-type well and an n-type well, wherein the p-type well is used to from the NMOS transistors and the n-type well is used to form the PMOS transistors. The p-type well and n-type well are spaced apart from each other, which undesirably increases the area occupied by the CMOS circuit.

As discussed in more detail in the above-referenced related applications, it is desirable to form semiconductor structures by engaging separate wafers together. The separate wafers are engaged together through one or more interconnects, which extend through a dielectric material region and provide an electrical connection. In some instances, the semiconductor structure is formed by engaging two wafers together, wherein one of the wafers includes scribe lines which extend between die. Ascribe line is a trench which extends along a surface of the wafer, and the wafer is cut along the scribe lines to separate the die from each other.

However, dishing can undesirably occur in response to cutting the wafer along the scribe lines. Dishing occurs in response to the force applied to the wafers when cutting along the scribe line. The wafers experience bowing in response to the force applied to the wafers when cutting along the scribe line. The interconnects can become disconnected in response to the bowing experienced by the wafers. Further, the wafers can become disengaged from each other in response to the bowing experienced by the wafers. Hence, it is desirable to reduce the amount of dishing.

### BRIEF SUMMARY OF THE INVENTION

The present invention involves a semiconductor circuit structure, and a method of forming the semiconductor circuit structure. The invention will be best understood from the following description when read in conjunction with the accompanying drawings.

### BRIEF DESCRIPTION OF THE DRAWINGS

FIG. 1a is a perspective view of a partially fabricated semiconductor structure, which is fabricated using growth.

FIG. 1b is a perspective view of a substrate and grown semiconductor layer of the semiconductor structure of FIG. 1a.

FIG. 1c is a side view of the semiconductor structure of FIG. 1b.

FIG. 2a is a perspective view of a partially fabricated semiconductor structure, which is fabricated using bonding.

FIG. 2b is a perspective view of substrates of the semiconductor structure of FIG. 2a bonded to each other.

FIG. 2c is a side view of the substrates of the bonded semiconductor structure of FIG. 2b bonded to each other, as shown in FIG. 2b.

FIGS. 3a, 3b and 3c are side view of steps of fabricating a stack of semiconductor regions using growth.

FIGS. 4a, 4b and 4c are side view of steps of fabricating a stack of semiconductor regions using ion implantation.

FIG. 5a is a partial side view of a bonded semiconductor structure which includes a ferroelectric memory device.

FIGS. 5b and 5c are perspective views of an interconnect region and memory circuit region included with the bonded semiconductor structure of FIG. 5a.

FIGS. 6 through 14 are cut-away side views of steps in manufacturing one embodiment of a semiconductor circuit structure, wherein the semiconductor circuit structure includes laterally oriented semiconductor devices.

FIG. 15a is a cut-away side view of one step in manufacturing the semiconductor circuit structure of FIGS. 6 through 14.

FIG. 15b is a perspective view of the semiconductor circuit structure of FIG. 15a.

FIG. 16a is a cut-away side view of one step in manufacturing the semiconductor circuit structure of FIGS. 6 through 14.

FIG. 16b is a close-up side view of the semiconductor circuit structure of FIG. 16a.

FIG. 17 is a cut-away side view of a die formed from the semiconductor circuit structure of FIGS. 16a and 16b, wherein the die includes laterally oriented semiconductor devices.

FIGS. 18 through 20 are cut-away side views of steps in manufacturing another embodiment of a semiconductor circuit structure, wherein the semiconductor circuit structure includes laterally and vertically oriented semiconductor devices.

FIG. 21a is a cut-away side view of one step in manufacturing the semiconductor circuit structure of FIGS. 18 through 20.

FIG. 21b is a perspective view of the semiconductor circuit structure of FIG. 21a.

FIGS. 22 and 23 are cut-away side views of more steps in manufacturing the semiconductor circuit structure of FIGS. 18 through 20, and FIGS. 21a and 21b.

FIGS. 24a and 24b are perspective views of a vertically oriented semiconductor device included in the semiconductor circuit structure of FIG. 23.

FIG. 25 is a cut-away side view of a die formed from the semiconductor circuit structure of FIG. 23, wherein the die includes laterally and vertically oriented semiconductor devices.

### DETAILED DESCRIPTION OF THE INVENTION

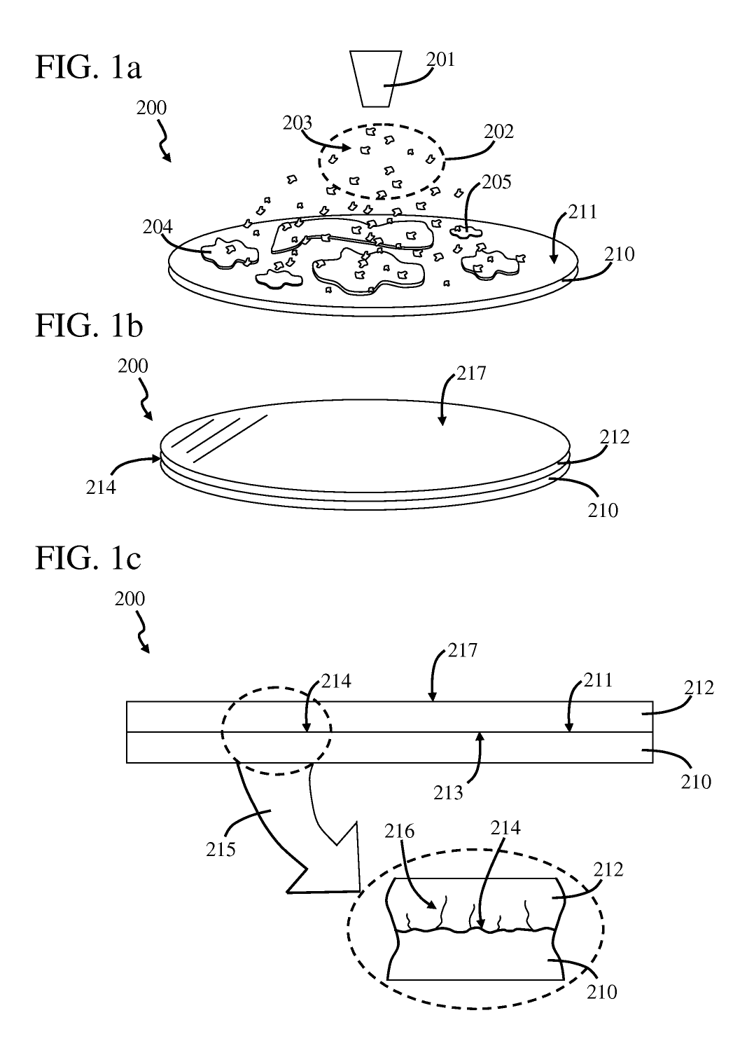

FIG. 1a is a perspective view of a partially fabricated grown semiconductor structure 200. In this embodiment, grown semiconductor structure 200 includes a substrate 210. Substrate 210 can be of many different types, such as a semiconductor substrate. A gaseous semiconductor material 203 is provided from a growth material source 201 in a region 202 proximate to a substrate surface 211 of substrate 210. It should be noted that, in general, more than one material sources are used to provide growth material and process gases. However, one material source is shown in FIG. 1a for simplicity and ease of discussion.

The semiconductor material discussed herein can be of many different types, such as silicon, germanium, silicon-germanium, gallium arsenide, gallium nitride, as well as alloys thereof. Further, substrate 210 can include a single layer structure, such as a silicon layer. However, in other embodiments, substrate 210 can include a multiple layer structure, such as a silicon-on-sapphire (SOS) and silicon-on-insulator (SOI) layer structure.

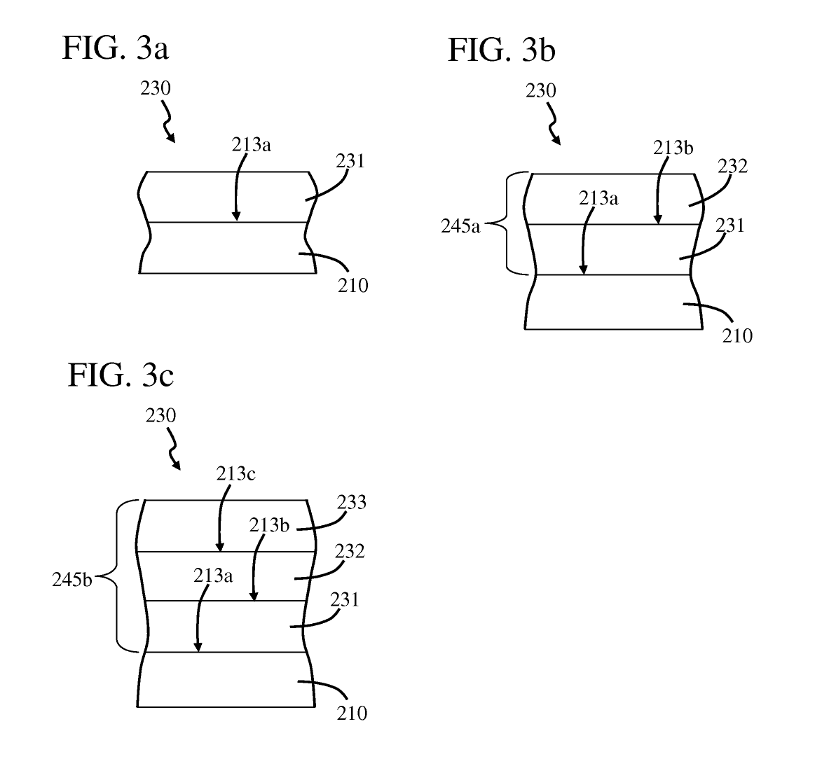

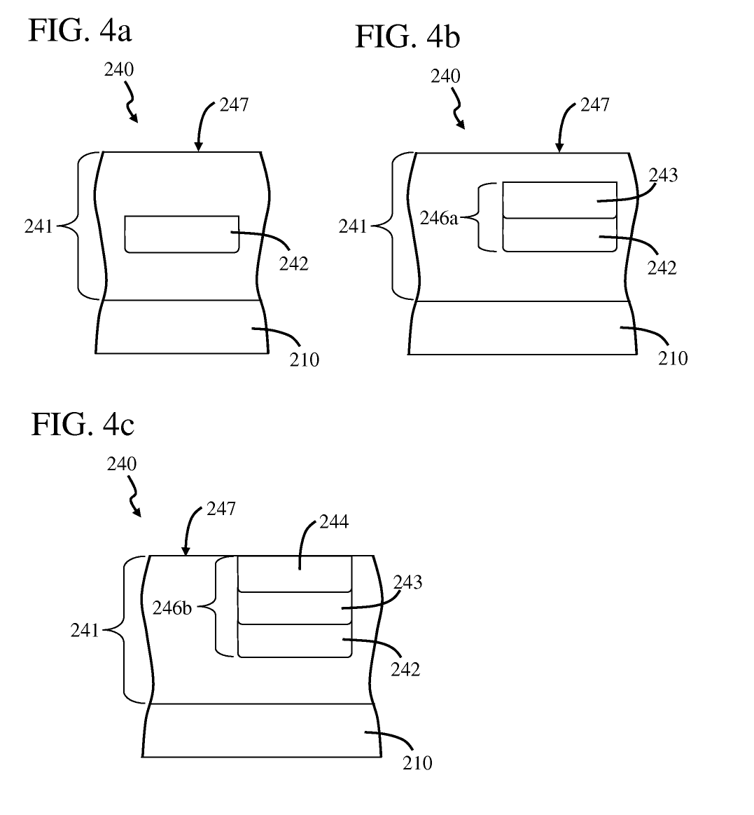

Portions of gaseous semiconductor material 203 engage surface 211 to form agglomerated semiconductor material 204 and 205. Portions of gaseous semiconductor material 203 engage surface 211 to form a grown semiconductor layer 212 on surface 211 of substrate 210, as shown in FIG. 1b, and a growth interface 214, as shown in FIG. 1c. FIG. 1b is a perspective view of substrate 210 and grown semiconductor layer 212, and FIG. 1c is a side view of grown semiconductor structure 200, as shown in FIG. 1b. Grown semiconductor layer 212 can be formed on substrate 210 in many different ways, such as by chemical vapor deposition, molecular beam epitaxy and sputtering, among others. It should be noted that, if desired, another semiconductor layer can be grown on a surface 217 of semiconductor layer 212 so that a stack of semiconductor regions is formed. More information regarding forming a stack of semiconductor regions is provided below with FIGS. 3a, 3b and 3c and FIGS. 4a, 4b and 4c.

As shown in FIG. 1c, a surface 213 of grown semiconductor layer 212 faces surface 211 of substrate 210, wherein surface 213 is opposed to surface 217. In particular, surface 213 is formed in response to the agglomeration of growth material on surface 211 so that a growth interface 214 is formed in response. Growth interface 214 is formed in response to gaseous semiconductor material 203 agglomerating on surface 211. In this example, growth interface 214 is formed in response to agglomerated semiconductor material 204 and 205 forming on surface 211, as shown in FIG. 1a. In this way, a grown semiconductor structure is fabricated using growth.

As indicated by an indication arrow 215, a growth defect 216 is formed in response to forming growth interface 214. Growth defect 216 can be of many different types, such as a dislocation. It should be noted that, in general, a number of growth defects 216 are formed in response to forming growth interface 214. The quality of growth interface 216 increases and decreases in response to decreasing and increasing, respectively, the number of growth defects 216.

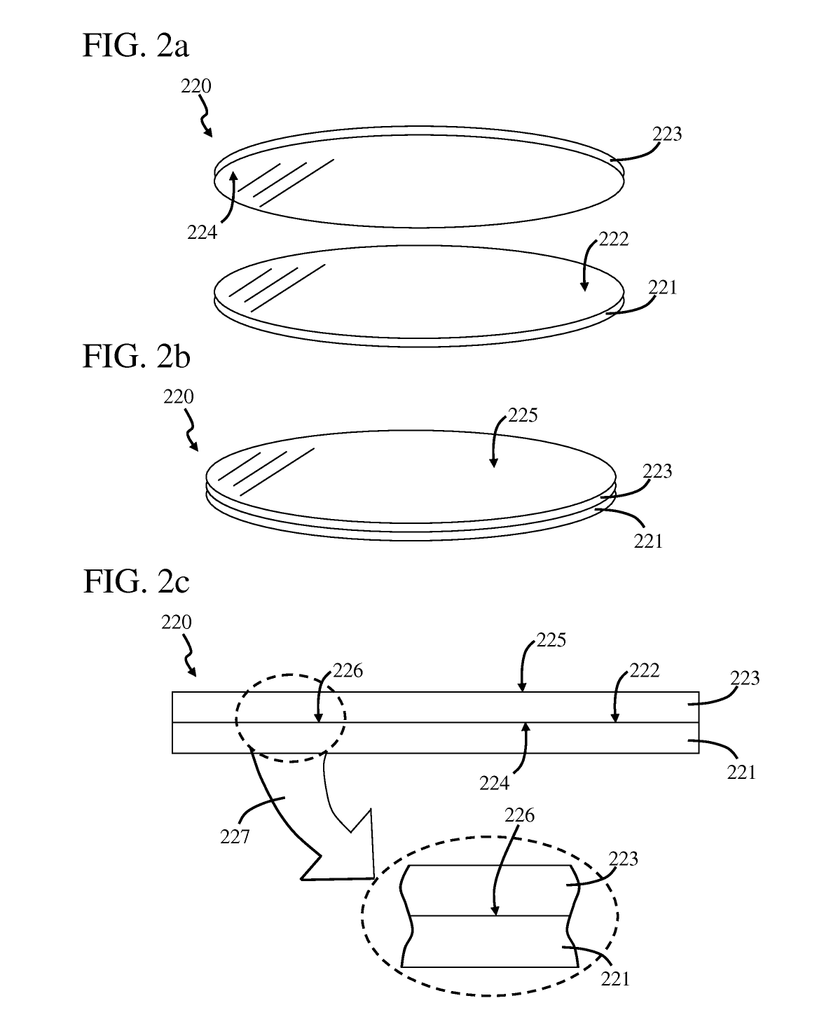

FIG. 2a is a perspective view of a partially fabricated bonded semiconductor structure 220. Bonded semiconductor structure 220 includes substrates 221 and 223. Substrates 221 and 223 can be of many different types, such as semiconductor substrates. Substrates 221 and 223 can include many different layer structures. For example, in some embodiments, substrates 221 and 223 each include conductive bonding layers adjacent to surfaces 222 and 224 of substrates 221 and 223, respectively.

As shown in FIGS. 2b and 2c, substrates 221 and 223 are moved towards each other so that a bonding interface 226 is formed in response. In particular, surfaces 222 and 224 of substrates 221 and 223, respectively, are moved towards each other so that a bonding interface 226 is formed in response to surfaces 222 and 224 being engaged. FIG. 2b is a perspective view of substrates 221 and 223 bonded to each other, and FIG. 2c is a side view of substrates 221 and 223 bonded to each other, as shown in FIG. 2b.

In FIG. 2c, surface 222 of substrate 221 faces surface 224 of substrate 223. In particular, surface 221 engages surface 224 so that bonding interface 226 is formed in response. It should be noted that bonding interface 226 is not formed in response to gaseous semiconductor material engaging surface 222. In particular, bonding interface 226 is not formed in response to the agglomerated semiconductor material on surface 222. In this way, a bonded semiconductor structure is fabricated using bonding. As indicated by an indication arrow 227, a growth defect is not formed in response to forming bonding interface 226. It should be noted that a signal experiences less attenuation in response to flowing through a bonding interface, and the signal experiences more attenuation in response to flowing through a growth interface. For example, a current signal experiences less attenuation in response to flowing through a bonding interface, and the current signal experiences more attenuation in response to flowing through a growth interface. Further, the noise of a signal increases more in response to flowing through a growth interface, and the noise of the signal increases less in response to flowing through a bonding interface.

It should also be noted that portions of the semiconductor structures discussed below are fabricated using growth, and other portions are fabricated using bonding. It should also be noted that, if desired, substrate 223 can include a stack of semiconductor regions. The stack of semiconductor regions of substrate 223 can be formed in many different ways, several of which will be discussed in more detail with FIGS. 3a, 3b and 3c and FIGS. 4a, 4b and 4c.

More information regarding bonding and growth interfaces can be found in related U.S. patent application Ser. No. 11/606,523, which is referenced above. Information regarding bonding and growth interfaces can also be found in U.S. Pat. Nos. 5,152,857, 5,695,557, 5,980,633 and 6,534,382.

A bonding interface is an interface that is formed in response to bonding material layers together. In one example of forming a bonding interface, first and second material layers are formed as separate layers, and moved towards each other so they engage each other and the bonding interface is formed in response. In this way, a bonding interface is established. It should be noted that heat is generally applied to the first and/or second material layers to facilitate the formation of the bonding interface. In a metal-to-metal bonding interface, the first and second material layers that are bonded together are conductive materials, such as metals. In a metal-to-dielectric bonding interface, one of the first and second material layers is a conductive material, and the other one is a dielectric material. In a metal-to-semiconductor bonding interface, one of the first and second material layers is a conductive material, and the other one is a semiconductor material.

A growth interface is an interface that is formed in response to growing a material layer on another material layer. In one example of forming a growth interface, a third material layer is formed, and a fourth material layer is grown on the third material layer so that the growth interface is formed in response. In this way, a growth interface is established. Hence, when forming a growth interface, third and fourth material layers are not formed as separate layers, and moved to engage each other.

In a metal-to-metal growth interface, the third and fourth material layers are conductive materials, such as metals. In a metal-to-dielectric growth interface, one of the third and fourth material layers is a conductive material, and the other one is a dielectric material. In a metal-to-semiconductor growth interface, one of the third and fourth material layers is a conductive material, and the other one is a semiconductor material. In a dielectric-to-dielectric growth interface the third and fourth materials are dielectric materials.

It should be noted that, in general, it is difficult to establish a metal-to-semiconductor growth interface, wherein the semiconductor material is grown on the metal layer. Further, it is difficult to grow a crystalline semiconductor material layer on a metal layer using semiconductor growth techniques, such as chemical vapor deposition. In most instances, the metal layer is formed on the semiconductor material. It is difficult to grow semiconductor material on a metal layer because metal layers do not operate as a very good seed layer for the semiconductor material. Hence, a significant amount of the semiconductor material will not agglomerate on the metal layer.

It is difficult to grow crystalline semiconductor material on the metal layer because metal layers tend to not be crystalline, and semiconductor material tends to have the crystal structure of the material it is formed on. Hence, if a semiconductor material is formed on a metal layer that includes non-crystalline conductive material, then the semiconductor material will also have a non-crystalline crystal structure and poor material quality. Thus, it is useful to bond crystalline semiconductor material to a metal layer to form a metal-to-semiconductor bonding interface.

In general, bonding and growth interfaces have different types and amounts of defects. For example, dislocations often extend from a growth interface in the direction of material growth. The difference between bonding and growth interfaces can be determined in many different ways, such as by using Transmission Electron Microscopy (TEM) to determine the type and amount of defects proximate to the interface. Information regarding TEM can be found in U.S. Pat. Nos. 5,892,225, 6,531,697, 6,822,233 and 7,002,152.

FIGS. 3a, 3b and 3c are side views of steps of fabricating a semiconductor structure 230, wherein structure 230 includes a stack of semiconductor regions formed using growth. It should be noted that, in this example, the stack of semiconductor regions generally includes two or more semiconductor layers. In this example, a semiconductor layer 231 is grown on substrate 210 so that a growth interface 213a is formed therebetween, as shown in FIG. 3a. A semiconductor layer 232 is grown on semiconductor layer 231 so that a growth interface 213b is formed therebetween, as shown in FIG. 3b. In FIG. 3b, a stack 245a includes semiconductor layers 231 and 232, and growth interfaces 213a and 213b. A semiconductor layer 233 is grown on semiconductor layer 232 so that a growth interface 213c is formed therebetween, as shown in FIG. 3c. In FIG. 3c, a stack 245b includes semiconductor layers 231, 232 and 233, and growth interfaces 213a, 213b and 213c. In this way, a stack of semiconductor regions is fabricated using growth. It should be noted that semiconductor layers 231, 232 and 233 can have many different doping types, several of which are discussed in more detail below.

FIGS. 4a, 4b and 4c are side views of steps of fabricating a semiconductor structure 240, wherein structure 240 includes a stack of semiconductor regions formed using ion implantation. It should be noted that, in this example, the stack of semiconductor regions generally includes two or more semiconductor regions formed by ion implantation, wherein the ion implanted semiconductor regions are formed in a semiconductor layer.

In this example, a semiconductor layer 241 is grown on substrate 210, wherein semiconductor layer 241 has a surface 247 positioned away from substrate 210. Implanted regions 242 and 243 are formed in semiconductor layer 241, as shown in FIGS. 4a and 4b. Implanted region 242 is formed in response to introducing a first dopant into semiconductor layer 241 through surface 247. Further, implanted region 243 is formed in response to introducing a second dopant into semiconductor layer 241 through surface 247. In this example, implanted region 242 is positioned between substrate 210 and implanted region 243. Further, implanted region 243 is positioned between surface 247 and implanted region 242. In FIG. 4b, a stack 246a includes semiconductor regions 242 and 243.

An implanted region 244 is formed in semiconductor layer 241, as shown in FIG. 4c. Implanted region 244 is formed in response to introducing a third dopant into semiconductor layer 241 through surface 247. In this example, implanted region 244 is positioned between substrate 210 and implanted regions 242 and 243. Further, implanted region 244 is positioned between surface 247 and implanted regions 242 and 243. In FIG. 4c, a stack 246b includes semiconductor regions 242, 243 and 244. In this way, a stack of semiconductor regions is fabricated using ion implantation. It should be noted that semiconductor regions 242, 243 and 244 can have many different doping types, several of which are discussed in more detail below. It should also be noted that a stack of semiconductor regions can be fabricated using one or more of the growth and implantation steps discussed above. For example, a semiconductor layer with a first conductivity type can be grown and implanted with an implant species to form a semiconductor region with a second conductivity type, wherein the semiconductor layer includes the semiconductor region with the second conductivity type.

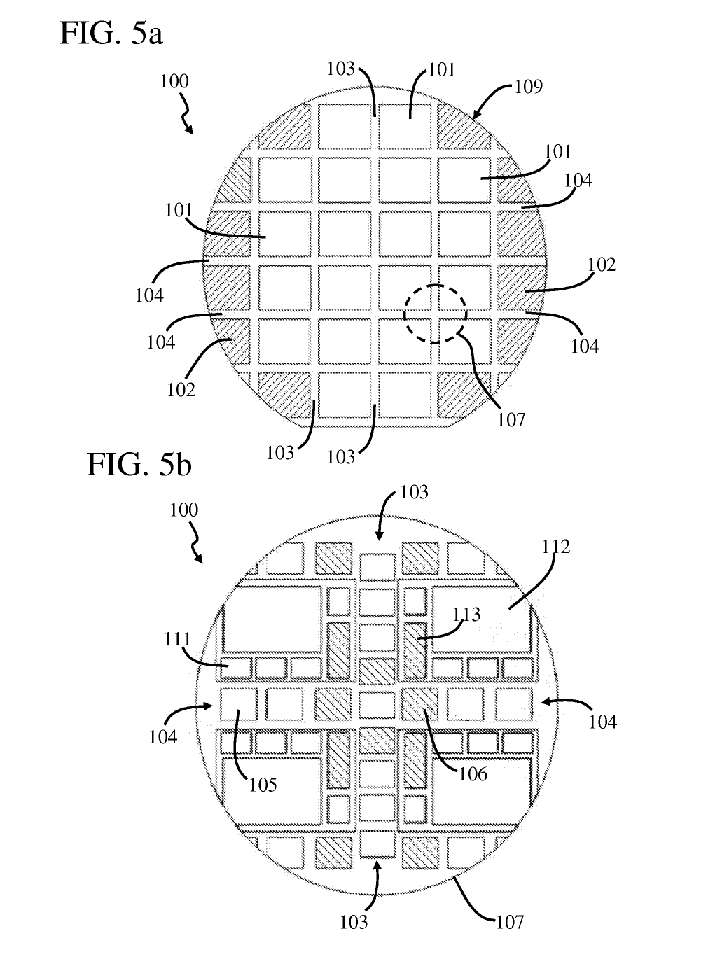

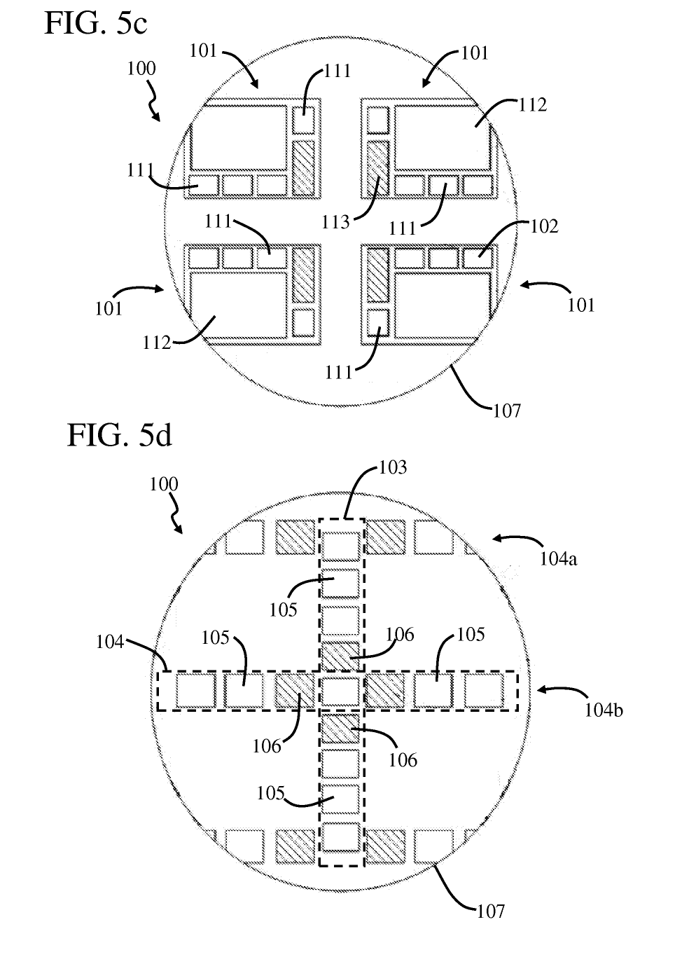

FIG. 5a is a top view of a wafer 100, and FIG. 5b is a top view of wafer 100 in a wafer region 107 of FIG. 5a. Wafer 100 can be of many different types, such as a semiconductor wafer which includes semiconductor material. The semiconductor material can be of many different types, such as silicon. In this embodiment, wafer 100 is formed using growth.

In this embodiment, wafer 100 includes a plurality of die 101. It should be noted that, in general, wafer 100 includes one or more die 101. Die 101 are typically formed in a repeated pattern along a major surface of wafer 100 to form an array of die. In general, the number of die included with wafer 100 increases and decreases as the size of wafer 100 increases and decreases, respectively. In particular, the number of die included with wafer 100 increases and decreases as the area of the major surface of wafer 100 increases and decreases, respectively. It should be noted that a die of wafer 100 is sometimes referred to as a chip.

Die 101 can be of many different types, such as a chip which includes electronic circuitry. The electronic circuitry can be of many different types, such as analog and/or digital circuitry. In this embodiment, die 101 includes electronic circuitry which includes a memory core circuit 112 and peripheral circuit 111. It should be noted that, in this embodiment, each die 101 of wafer 100 includes memory core circuit 112 and peripheral circuit 111. In general, die 101 includes one or more memory core circuits 113. However, in this embodiment, die 101 includes a single memory core circuit 112. Further, in general, die 101 includes one or more peripheral circuit 111. However, in this embodiment, die 101 includes four peripheral circuits 111.

Die 101 can include many different types of memory, such as read only memory (ROM) and/or random access memory. Examples of different types of memory include dynamic random access memory (DRAM), static random access memory (SRAM) and FLASH memory, among others. Examples of electronic circuitry and memory can be found in U.S. Pat. Nos. 4,704,785, 4,829,018, 4,939,568, 5,087,585, 5,093,704, 5,106,775, 5,266,511, 5,308,782, 5,355,022, 5,554,870, 5,627,106, 5,835,396, 5,977,579, 5,998,808, 6,153,495, 6,222,251, 6,331,468, 6,600,173, 6,630,713, 6,677,204, 6,943,067, 6,943,407, 6,995,430, 7,078,739, as well as U.S. Patent Application Nos. 20020024140, 20020025604, 20020141233, 20030067043, 20030113963, 20030139011, 20040113207, 20040155301 and 20040160849.

It should be noted that die 101 can include horizontally and/or vertically oriented semiconductor devices. It should also be noted that memory core circuit 112 is often referred to as embedded memory. Embedded memory is typically positioned so that it is carried by the same support substrate as the processor and/or control circuitry. More information regarding embedded memory can be found in the above-identified references, such as U.S. patent application Ser. No. 11/092,521, entitled “Electronic Circuit with Embedded Memory”. One type of embedded memory is often referred to as cache memory, such as L1 and L2 cache memory, wherein the embedded memory is embedded with a central processing unit (CPU). In another embodiment, the embedded memory is embedded with a microcontroller. Examples of a CPU are disclosed in U.S. Pat. Nos. 5,737,748 and 5,829,026, and examples of a microcontroller are disclosed in U.S. Pat. Nos. 6,009,496 and 6,854,067.

Stand-alone memory is typically positioned so that it and processor circuitry are carried by different support substrates. It should be noted, however, that stand-alone memory can include control circuitry carried on the same carrier substrate as the memory region. Stand-alone memory is typically included with a memory module, such as those disclosed in U.S. Pat. Nos. 6,742,067, 6,751,113 and 6,535,411. These types of memory modules are pluggable into a printed circuit board, wherein they are in communication with the processor circuitry through the printed circuit board. A printed circuit board generally includes an insulative substrate and conductive interconnects. The processor circuitry and memory region are included in computer chips which are connected together with the conductive interconnects of the printed circuit board. Examples of printed circuit boards are disclosed in U.S. Pat. Nos. 6,621,168 and 6,787,920.

Each of die 101 are separated by scribe lines 103 and 104 which extend through a surface 108 of wafer 100 and between die 102. Scribe lines 103 and 104 are trenches which extend through surface 108. It should be noted that die 101 are shown in FIG. 5C and scribe lines 103 and 104 are shown in FIG. 5d. Scribe lines 103 and 104 extend perpendicular to each other so that die 101 are rectangular in shape. Some of die 101 extend through an edge 109 of wafer 100, and are denoted as edge die 102. Edge 109 extends around the outer periphery of wafer 100. Edge die 102 are formed to reduce the amount of dishing experienced by wafer 100 in response to cutting wafer 100 along scribe lines 103 and 104.

In this embodiment, die 101 includes a dummy pattern 113 positioned adjacent to a scribe line, such as scribe lines 103 and 104. Dummy pattern 113 is included with die 101 to reduce the amount of dishing experienced by wafer 100 in response to cutting wafer 100 along scribe lines 103 and 104.

In this embodiment, scribe lines 103 and 104 include alignment keys 105 and scribe line dummy patterns 106. Alignment keys 105 are used to align another wafer with wafer 100 so that they can be engaged together in a desired alignment. The alignment is chosen to facilitate the ability to electrically connect wafer 100 to the other wafer through the interconnects. As will be discussed in more detail below, scribe line dummy patterns 106 are included with scribe lines 103 and 104 to reduce the amount of dishing experienced by wafer 100 in response to cutting wafer 100 along scribe lines 103 and 104.

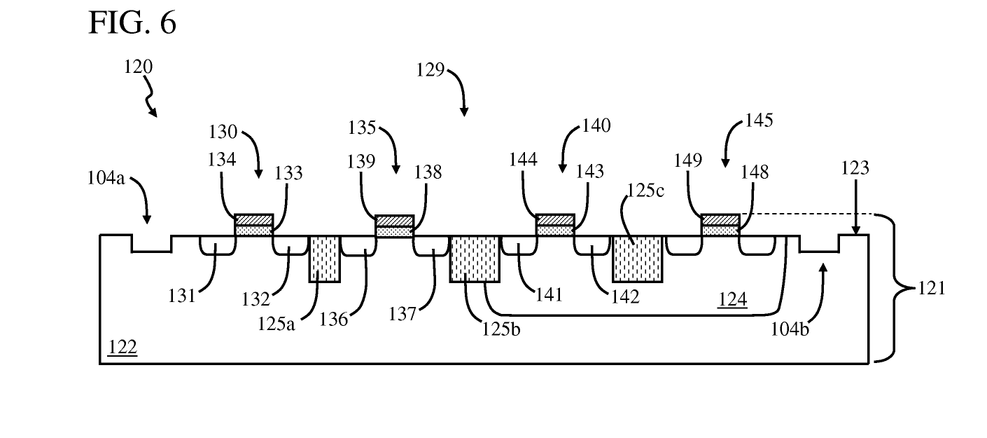

FIG. 6 is a cutaway side view of a semiconductor circuit structure 120. It should be noted that semiconductor circuit structure 120 can be included in a wafer, such as wafer 100 of FIGS. 5a, 5b, 5c and 5d. In particular, semiconductor circuit structure 120 can be included in a die, such as die 101. Semiconductor circuit structure 120 can be included in many different portions of die 101, such as in peripheral circuit 111 and memory core circuit 112.

In this embodiment, semiconductor circuit structure 120 includes a support substrate 121, which includes a support substrate body 122. Support substrate body 122 can include many different types of materials, such as semiconductor material. The semiconductor material of support substrate body 122 can have many different conductivity types. For example, regions of support substrate body 122 can be intrinsically doped, n-type doped and p-type doped.

In this embodiment, support substrate body 122 carries electronic circuitry 129, which is positioned proximate to a major surface 123 of support substrate body 122. In some embodiments, electronic circuitry 129 includes processor and/or control circuitry. The processor circuitry processes data, such as digital data, and the control circuitry controls the flow of the data, such as sending it to and retrieving it from a memory region.

Electronic circuitry 129 can include many different types of electronic devices. In this embodiment, the electronic device includes a transistor. The transistor can be of many different types, such as a bipolar junction transistor. In this embodiment, however, electronic circuitry 129 includes complementary metal oxide semiconductor (CMOS) circuitry, wherein the CMOS circuitry includes metal oxide field effect transistors (MOSFETs). The MOSFETs can be of many different types, such as p-channel and n-channel MOSFETs. In this embodiment, support substrate body 122 carries both p-channel and n-channel MOSFET because electronic circuitry 129 includes CMOS circuitry.

In this embodiment, support substrate body 122 carries a transistor 130, which includes a source 131 and drain 132, which extend through support substrate body 122. Source 131 and drain 132 have a different doping type than support substrate body 122. Transistor 130 includes a control dielectric 133 positioned on surface 123, wherein control dielectric 133 extends between source 131 and drain 132. Transistor 130 includes a control terminal 134 positioned on control dielectric 133.

In operation, the conductivity of support substrate body 122 between source 131 and drain 132 is adjustable in response to adjusting a control signal provided to control terminal 134. In this way, transistor 130 operates as a MOSFET.

In this embodiment, support substrate body 122 carries a transistor 135, which includes a source 136 and drain 137, which extend through support substrate body 122. Source 136 and drain 137 have a different doping type than support substrate body 122. Transistor 135 includes a control dielectric 138 positioned on surface 123, wherein control dielectric 138 extends between source 136 and drain 137. Transistor 135 includes a control terminal 139 positioned on control dielectric 138.

In operation, the conductivity of support substrate body 122 between source 136 and drain 137 is adjustable in response to adjusting a control signal provided to control terminal 139. In this way, transistor 135 operates as a MOSFET. It should be noted that support substrate 121 includes an isolation region 125a which extends between transistors 130 and 135. Isolation region 125a provides isolation between transistors 130 and 135. For example, isolation region 125a restricts the ability of current to flow between drain region 132 and source region 136 through support substrate body 122. The isolation regions discussed herein can be formed in many different ways, such as by etching a trench and then filling the trench with an isolation material. For example, in some embodiments, the trench of the isolation region is filled with an oxide by using a High Density Plasma (HDP).

In this embodiment, support substrate body 122 carries a transistor 140, which includes a source 141 and drain 142, which extend through support substrate body 122. In particular, source 141 and drain 142 extend through a well region 124 of support substrate body 122, wherein well region 124 has a different doping type than support substrate body 122. Source 141 and drain 142 have a different doping type than well region 124, and source 141 and drain 142 have the same doping type as support substrate body 122. Transistor 140 includes a control dielectric 143 positioned on surface 123, wherein control dielectric 143 extends between source 141 and drain 142. Transistor 140 includes a control terminal 144 positioned on control dielectric 143.

In operation, the conductivity of well region 124 between source 141 and drain 142 is adjustable in response to adjusting a control signal provided to control terminal 144. In this way, transistor 140 operates as a MOSFET. It should be noted that support substrate 121 includes an isolation region 125b which extends between transistors 135 and 140. Isolation region 125b provides isolation between transistors 135 and 140. For example, isolation region 125b restricts the ability of current to flow between drain region 137 and source region 141 through support substrate body 122. Further, isolation region 125b restricts the ability of current to flow between drain region 137 and source region 141 through well region 124.

In this embodiment, support substrate body 122 carries a transistor 145, which includes a source 146 and drain 147, which extend through support substrate body 122. In particular, source 146 and drain 147 extend through well region 124 of support substrate body 122. Source 146 and drain 147 have a different doping type than well region 124, and source 146 and drain 147 have the same doping type as support substrate body 122. Transistor 145 includes a control dielectric 148 positioned on surface 123, wherein control dielectric 148 extends between source 146 and drain 147. Transistor 145 includes a control terminal 149 positioned on control dielectric 148.

In operation, the conductivity of well region 124 between source 146 and drain 147 is adjustable in response to adjusting a control signal provided to control terminal 149. In this way, transistor 145 operates as a MOSFET. It should be noted that support substrate 121 includes an isolation region 125c which extends between transistors 140 and 145. Isolation region 125c provides isolation between transistors 140 and 145. For example, isolation region 125c restricts the ability of current to flow between drain region 142 and source region 146 through well region 124.

It should be noted that transistors 130, 135, 140 and 145 are positioned between adjacent scribe lines 103 and adjacent scribe lines 104 (FIGS. 5a and 5d), wherein scribe lines 103 and 104 extend through support substrate 121. In particular, scribe lines 103 and 104 extend through support substrate surface 123 of support substrate 121. In FIG. 6a, transistors 130, 135, 140 and 145 are shown positioned between adjacent scribe lines 104, which are denoted as scribe lines 104a and 104b in FIGS. 5d and 6a.

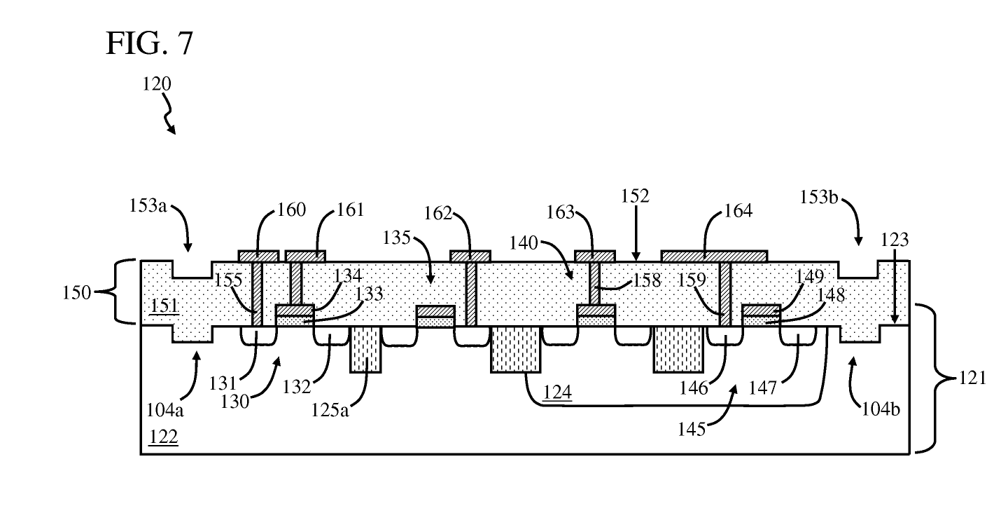

FIG. 7 is a cut-away side view of semiconductor circuit structure 120, wherein support substrate 121 of FIG. 6 carries an interconnect region 150 having a surface 174. In general, interconnect region 150 includes an interconnect which extends through a dielectric material region. The interconnects of interconnect region 150 can include many different types of conductive materials, such as aluminum (Al), copper (Cu), molybdenum (Mo), titanium (Ti) and tungsten (W). In some embodiments, the interconnects of interconnect region 150 include a refractory metal. In some embodiments, the interconnects of interconnect region 150 include a nitride material, such as titanium nitride (TiN), tantalum nitride (TaN), zirconium nitride (ZrN), and alloys thereof.

The dielectric material of interconnect region 150 can include many different types of material, such as silicon dioxide and silicon nitride. The dielectric material of interconnect region 150 can also include a glass material, such as phosphosilicate glass (PSG), borophosphosilicate glass (BPSG), undoped silicate glass (USG) and plasma enhanced-tetraethylorthosilicate glass (PE-TEOS), among others. The dielectric material of interconnect region 150 can be formed in many different ways, such as by using chemical vapor deposition (CVD) and physical vapor deposition (PVD).

In some embodiments, the interconnect includes a conductive contact and, in other embodiments, the interconnect includes a conductive via. In some embodiments, the interconnect includes a conductive contact connected to a conductive via. It should be noted that the conductive contact extends parallel to surface 123, and the conductive via extends perpendicular with surface 123. In general, the interconnect of interconnect region 150 allows a signal to flow between support substrate surface 123 and surface 174.

The interconnects of interconnect region 150 can be formed in many different ways. In some embodiments, an interconnect opening is formed through the dielectric material using anisotropic etching. The material of the interconnect is deposited through the interconnect opening. It should be noted that the interconnects of interconnect region 150 are different from through silicon vias (TSVs) because the interconnects extend through a dielectric material region instead of a semiconductor material region, such as silicon. Further, the interconnects of interconnect region 150 are different from through silicon vias (TSVs) because the interconnects extend through a thinner dielectric material region instead of a thicker semiconductor material region. For example, the dielectric material through which the interconnects extend is typically less than one micron thick. Hence, the length of the via is typically less than one micron. In some embodiments, the dielectric material through which the interconnects extend is typically less than 0.5 microns thick. Hence, the length of the via is typically less than 0.5 microns. The length of the via is the dimension of the via perpendicular to surface 123 of support substrate body 122. It should also be noted that a width of a via of interconnect region 150 is less than a width of a control terminal of a MOSFET included with electronic circuitry 129. The width of the via is the dimension of the via parallel to surface 123 of support substrate body 122. In some embodiments, the width of the via is less than 0.2 microns. In some embodiments, the width of the via is less than 0.1 microns.

It should also be noted that the dielectric material of interconnect region 150 has a larger permittivity than the permittivity of the semiconductor material of support substrate body 122. It should be noted that the conductive material of the interconnect of interconnect region 150 has a larger conductivity than the conductivity of the dielectric material of interconnect region 150. Further, it should be noted that the conductive material of the interconnect of interconnect region 150 has a larger conductivity than the conductivity of the semiconductor material of support substrate body 122.

In this embodiment, interconnect region 150 includes a dielectric material region 151 positioned on surface 123, and a plurality of interconnects which extend through dielectric material region 151. It should be noted that portions of dielectric material region 151 extend through scribe lines 104a and 104b.

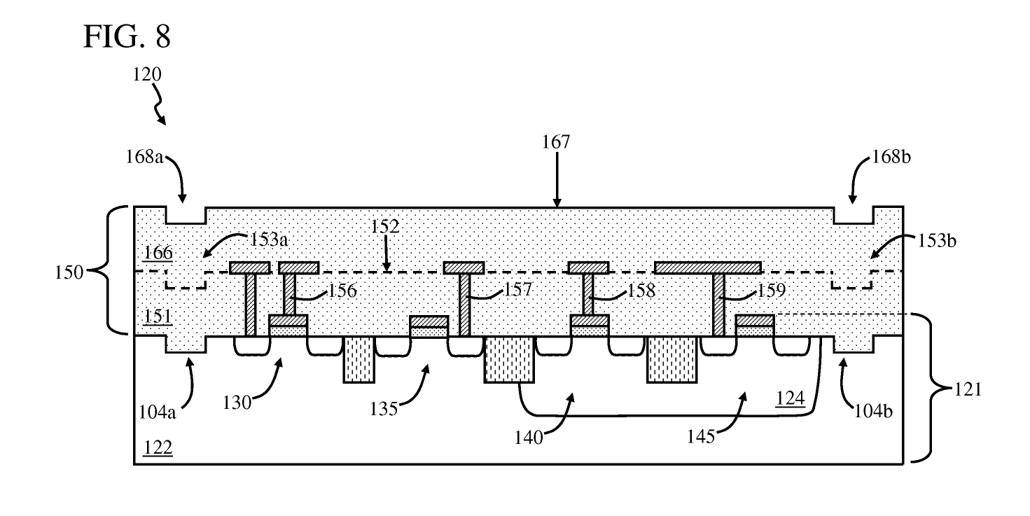

The interconnects of interconnect region 150 can be connected together in many different ways. In this embodiment, interconnect region 150 includes a conductive contact 160 positioned on surface 174, and a conductive via 155 connected to source region 131 and conductive contact 160. In this embodiment, interconnect region 150 includes a conductive contact 161 positioned on surface 174, and a conductive via 156 (FIG. 8) connected to control terminal 134 and conductive contact 161. In this embodiment, interconnect region 150 includes a conductive contact 162 positioned on surface 174, and a conductive via 157 (FIG. 8) connected to drain region 137 and conductive contact 162. In this embodiment, interconnect region 150 includes a conductive contact 163 positioned on surface 174, and a conductive via 158 connected to control terminal 144 and conductive contact 163. In this embodiment, interconnect region 150 includes a conductive contact 164 positioned on surface 174, and a conductive via 159 connected to source 146 and conductive contact 164.

In this embodiment, interconnect region 150 includes scribe lines 153a and 153b which extend through surface 174. Scribe lines 153a and 153b are aligned with scribe lines 104a and 104b, respectively. Scribe lines 104a and 153a are aligned so that scribe lines 104a and 153a can be both cut through in response to cutting through dielectric material region 151 between surfaces 123 and 152. Further, scribe lines 104b and 153b are aligned so that scribe lines 104b and 153b can both be cut through in response to cutting through dielectric material region 151 between surfaces 123 and 152.

Scribe lines 104a and 153a are aligned with each other to reduce the amount of dishing experienced by support substrate 121 and interconnect region 150 in response to cutting through scribe lines 104a and 153a. Further, scribe lines 104b and 153b are aligned with each other to reduce the amount of dishing experienced by support substrate 121 and interconnect region 150 in response to cutting through scribe lines 104b and 153b. In this way, support substrate body 122 is less likely to experience bowing in response to the force applied to semiconductor circuit structure 120 when cutting along the scribe lines.

The interconnects of interconnect region 150 are positioned between scribe lines 153a and 153b so they are less likely to become disengaged from each other in response to the bowing experienced by semiconductor circuit structure 120. For example, conductive via 155 is positioned between scribe lines 153a and 153b so that it is less likely to become disconnected from conductive contact 160 and source 131 in response to cutting through scribe lines 104a and 153a. Conductive via 159 is positioned between scribe lines 153a and 153b so that it is less likely to become disconnected from conductive contact 164 and source 146 in response to cutting through scribe lines 104b and 153b.

It should be noted that interconnect region 150 generally includes one or more dielectric material regions. For example, interconnect region 150 of FIG. 7 includes a single dielectric material region because it includes dielectric material region 151. However, interconnect region 150 can include a plurality of dielectric material regions, as will be discussed in more detail presently.

FIG. 8 is a cut-away side view of semiconductor circuit structure 120 of FIG. 7, wherein interconnect region 150 includes two dielectric material regions. In FIG. 8, interconnect region 150 includes a dielectric material region 166 positioned on surface 174, so that interconnect region 150 includes two dielectric material regions. It should be noted that portions of dielectric material region 166 extend through scribe lines 153a and 153b. It should also be noted that the dielectric material of region 166 is typically the same as the dielectric material of dielectric material region 151, although it can be different, if desired.

In this embodiment, interconnect region 150 includes scribe lines 168a and 168b which extend through a surface 167 of dielectric material region 166. It should be noted that dielectric material region 166 extends between surfaces 152 and 167. Scribe line 168a is aligned with scribe lines 104a and 153a. Scribe lines 104a, 153a and 168a are aligned so that scribe lines 104a, 153a and 168a can be cut through in response to cutting through dielectric material regions 151 and 166 between surfaces 123 and 167. Scribe line 168b is aligned with scribe lines 104b and 153b. Scribe lines 104b, 153b and 168b are aligned so that scribe lines 104b, 153b and 168b can be cut through in response to cutting through dielectric material regions 151 and 166 between surfaces 123 and 167.

Scribe lines 104a, 153a and 168a are aligned with each other to reduce the amount of dishing experienced by support substrate 121 and interconnect region 150 in response to cutting through scribe lines 104a, 153a and 168a. Further, scribe lines 104b, 153b and 168b are aligned with each other to reduce the amount of dishing experienced by support substrate 121 and interconnect region 150 in response to cutting through scribe lines 104b, 153b and 168b. In this way, support substrate body 122 is less likely to experience bowing in response to the force applied to semiconductor circuit structure 120 when cutting along the scribe lines. The interconnects of interconnect region 150 are positioned between scribe lines 168a and 168b, so they are less likely to become disengaged from each other in response to the bowing experienced by semiconductor circuit structure 120, as discussed in more detail above.

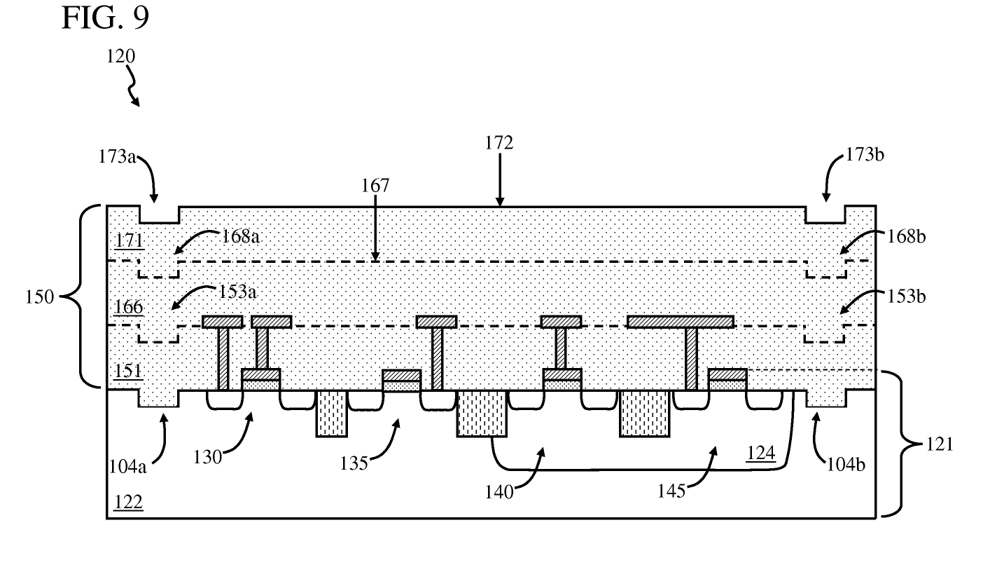

FIG. 9 is a cut-away side view of semiconductor circuit structure 120 of FIG. 8, wherein interconnect region 150 includes three dielectric material regions. In FIG. 9, interconnect region 150 includes a dielectric material region 171 positioned on surface 167. It should be noted that portions of dielectric material region 171 extend through scribe lines 168a and 168b. It should also be noted that the dielectric material of region 171 is typically the same as the dielectric material of dielectric material regions 151 and 166. although it can be different, if desired.

In this embodiment, interconnect region 150 includes scribe lines 173a and 173b which extend through a surface 172 of dielectric material region 171. It should be noted that dielectric material region 171 extends between surfaces 167 and 172. Scribe line 173a is aligned with scribe lines 104a, 153a and 168a. Scribe lines 104a, 153a, 168a and 173a are aligned so that scribe lines 104a, 153a, 168a and 173a can be cut through in response to cutting through dielectric material regions 151, 166 and 171 between surfaces 123 and 172. Scribe line 173b is aligned with scribe lines 104b, 153b and 168b. Scribe lines 104b, 153b, 168b and 173b are aligned so that scribe lines 104b, 153b, 168b and 173b can be cut through in response to cutting through dielectric material regions 151, 166 and 171 between surfaces 123 and 172.

Scribe lines 104a, 153a, 168a and 173a are aligned with each other to reduce the amount of dishing experienced by support substrate 121 and interconnect region 150 in response to cutting through scribe lines 104a, 153a, 168a and 173a. Further, scribe lines 104b, 153b, 168b and 173b are aligned with each other to reduce the amount of dishing experienced by support substrate 121 and interconnect region 150 in response to cutting through scribe lines 104b, 153b, 168b and 173b. In this way, support substrate body 122 is less likely to experience bowing in response to the force applied to semiconductor circuit structure 120 when cutting along the scribe lines. The interconnects of interconnect region 150 are positioned between scribe lines 173a and 173b, so they are less likely to become disengaged from each other in response to the bowing experienced by semiconductor circuit structure 120, as discussed in more detail above.

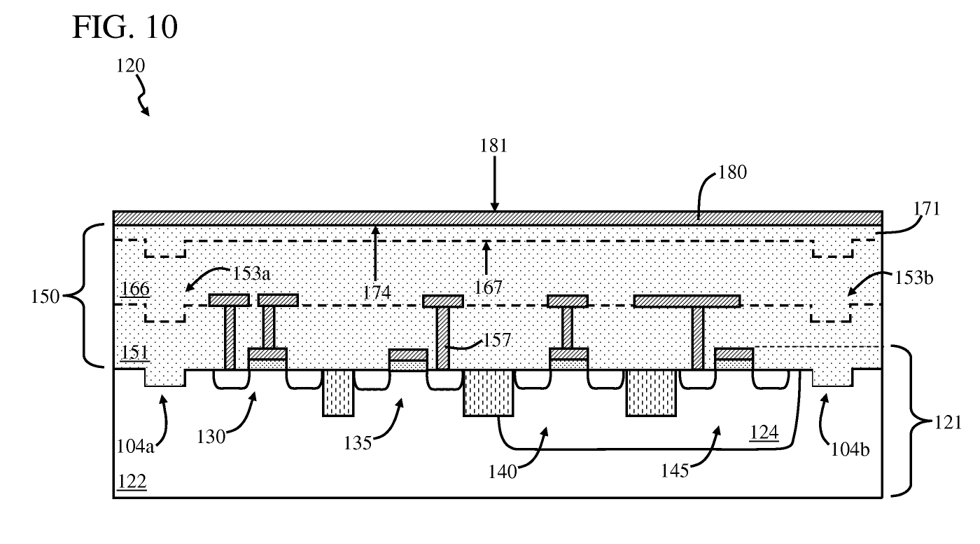

FIG. 10 is a cut-away side view of semiconductor circuit structure 120 of FIG. 9, wherein dielectric material region 171 is formed to have an exposed surface 174 opposed to surface 167. In some embodiments, exposed surface 174 is a planarized surface. Dielectric material region 171 can be planarized in many different ways, such as by using chemical mechanical polishing (CMP). In this embodiment, dielectric material region 171 is planarized so that interconnect region 150 does not include scribe lines 173a and 173b, as shown in FIG. 9.

In this embodiment, a conductive bonding layer 180 is positioned on surface 174. Conductive bonding layer 180 is positioned on a planarized surface when surface 174 is a planarized surface. Conductive bonding layer 180 can include many different types of materials, such as the material included with the interconnects of interconnect region 150.

In some embodiments, conductive bonding layer 180 includes a material that can be deposited on surface 174 at a temperature less than about 450° C. It is desirable to deposit the material of conductive bonding layer 180 at a temperature that is less likely to damage the electronic devices carried by support substrate 121, such as transistors 130, 135, 140 and 145. In one embodiment, the material of conductive bonding layer 180 has a lower melting point than the material of the interconnects of interconnect region 150. The material of conductive bonding layer 180 can be deposited in many different ways, such as by using CVD and PVD. It should be noted that, in some embodiments, an exposed surface 181 of conductive bonding layer 180 is planarized.

In some embodiments, conductive bonding layer 180 includes an adhesive. The adhesive can be of many different types, such as a photo-setting adhesive. Some types of photo-setting adhesive are reaction-setting adhesives, thermal-setting adhesives, UV-setting adhesives, or anaerobe adhesives. Further, conductive bonding layer 180 can include an epoxy, acrylate, or silicon adhesives.

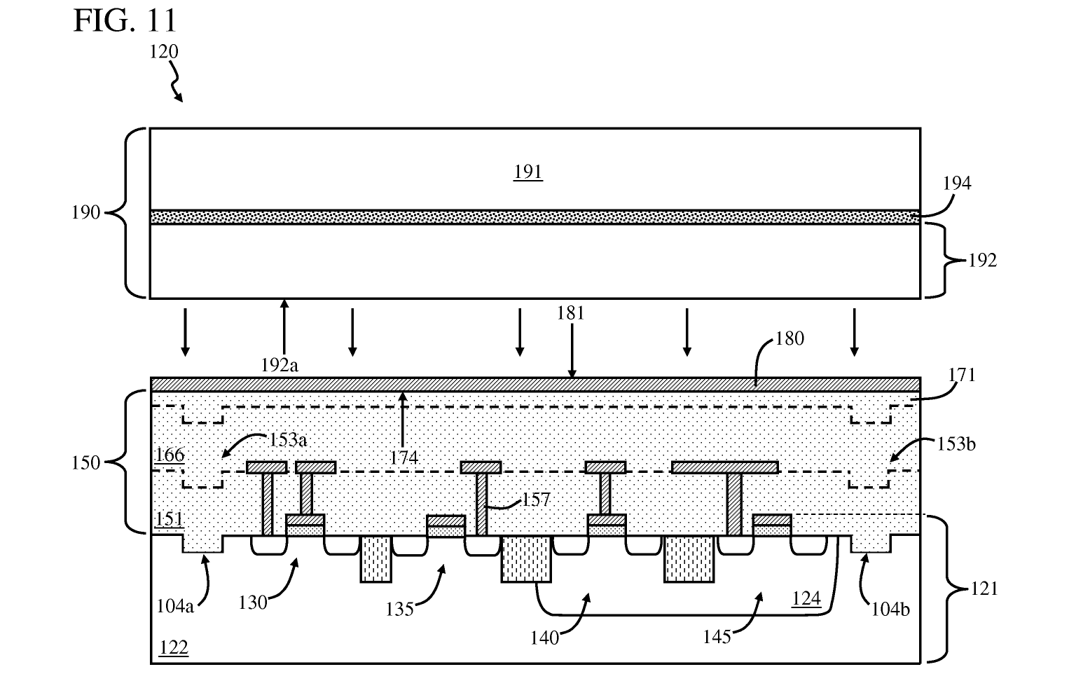

In FIG. 11, a donor structure 190 is provided and positioned proximate to semiconductor circuit structure 120 of FIG. 10. In some embodiments, donor structure 190 is a wafer. In some embodiments, donor structure 190 is a wafer which does not include die. In some embodiments, donor structure 190 has a major surface that is the same size as a major surface of support substrate 121. For example, in some embodiments, donor structure 190 and support substrate 121 are both twelve inch wafers.

In this embodiment, donor structure 190 includes a support substrate 191 which carries a detach region 194 and device substrate 192. In some embodiments, detach region 194 and device substrate 192 are blanket layers of material. More information regarding donor structure 190 and detach region 194 can be found in the above-identified U.S. patent and patent applications, such as U.S. patent application Ser. No. 11/092,501. Detach region 194 extends between support substrate 191 and device substrate 192 so that device substrate 192 can be separated from support substrate 191, as will be discussed in more detail below.

Detach region 194 can include many different types of materials, such as a porous material and dielectric material. An example of porous material is porous semiconductor material, such as porous silicon, and examples of a dielectric material include silicon oxide and silicon nitride. In some embodiments, detach region 194 includes a material having microholes extending therethrough, which decrease its mechanical strength. In some embodiments, the material of detach region 194 includes a nitride, such as silicon nitride, or an organic bonding layer. In some embodiments, the material of detach region 194 includes a strained semiconductor layer, such as a strained silicon germanium layer. Detach region 194 is useful because it does not require the use of ion implantation, such as when using exfoliating implants, as disclosed in U.S. Pat. No. 6,600,173. Exfoliating implants cause severe damage in response to the heavy dosage required, and it is necessary to reduce the damage with a high temperature anneal. However, the high temperature anneal can damage the electronic devices carried by support substrate 121, such as transistors 130, 135, 140 and 145.

It should be noted that device substrate 192 can include many different types of materials, but it generally includes a semiconductor material. The semiconductor material can be of many different types, such as silicon. The semiconductor material is typically crystalline semiconductor material and is formed to have desirable electrical properties. Single crystalline semiconductor material can have localized defects, but it is generally of better material quality than amorphous or polycrystalline semiconductor material. Further, device substrate 192 can include one or more semiconductor layers, but here it is shown as including a single semiconductor layer for simplicity.

In one embodiment, device substrate 192 of FIG. 11 consists essentially of crystalline semiconductor material. In another embodiment, device substrate 192 of FIG. 11 consists of crystalline semiconductor material. It should be noted that in these embodiments, device substrate 192 can include defects, such as impurities, as well as dopants to provide it with a desired conductivity type.

It should also be noted that device substrate 192 is typically doped so it has a desired doping concentration. In some embodiments, device substrate 192 is doped so that its doping concentration is uniform between a surface 192a and detach region 194, wherein device substrate 192 extends between surface 192a and detach region 194. In another embodiment, device substrate 192 is doped so that its doping concentration is non-uniform between surface 192a and device substrate 192. In these embodiments, the doping concentration of device substrate 192 can be less proximate to surface 192a and more proximate to detach region 192. Further, in these embodiments, the doping concentration of device substrate 192 can be more proximate to surface 192a and less proximate to detach region 192, as discussed in more detail in U.S. patent application Ser. No. 12/040,642. It should be noted that, in some embodiments, surface 192a is a planarized surface. Surface 192a can be planarized in many different ways, such as by using CMP.

It should be noted that device substrate 192, as shown in FIG. 11, does not carry an electronic device before it is coupled to support substrate 121, as will be discussed in more detail below. For example, in FIG. 11, device substrate 192 does not include a horizontal transistor, and device substrate 192 does not include a vertical transistor. In this way, device substrate 192 consists essentially of a semiconductor material before it is coupled to support substrate 121. In some embodiments, device substrate 192 consists of a semiconductor material before it is coupled to support substrate 121.

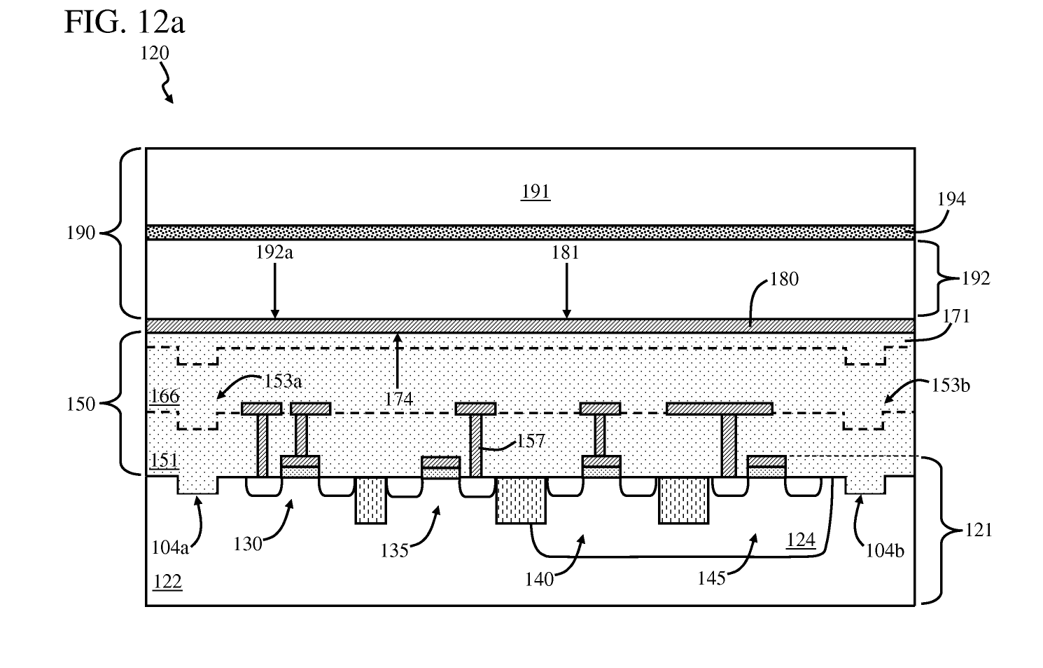

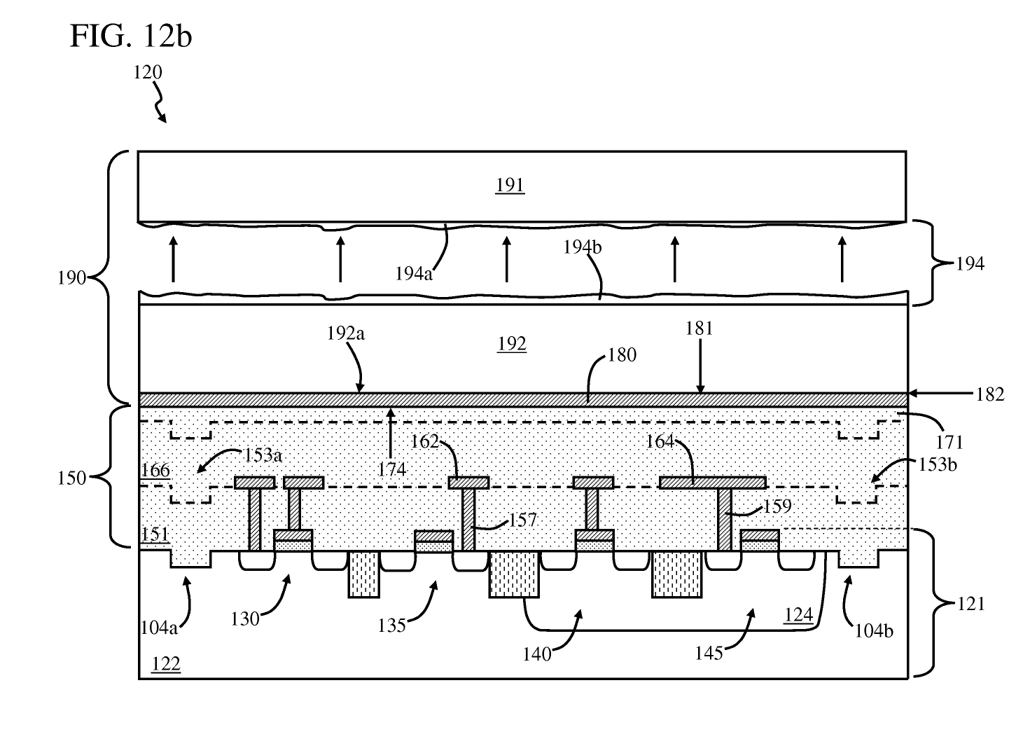

In FIG. 12a, device substrate 192 is included with semiconductor circuit structure 120 by coupling it to support substrate 121. Device substrate 192 can be coupled to support substrate 121 in many different ways, such as by bonding. In this embodiment, device substrate 192 is coupled to support substrate 121 by bonding device substrate 192 to conductive bonding layer 180. In particular, surface 192a of device substrate 192 is bonded to surface 181 of conductive bonding layer 180 to form a bonding interface 182 (FIG. 12a). In this way, donor structure 190 is coupled to support substrate 121 through a bonding interface and interconnect region 150. Further, device substrate 192 is coupled to support substrate 121 through a bonding interface and interconnect region 150.

It should be noted that surface 192a of device substrate 192 is bonded to a planarized surface when surface 181 of conductive bonding layer 180 is a planarized surface. In this way, bonding interface 182 is positioned proximate to a planarized surface of conductive bonding layer 180. A planarized surface of device substrate 192 is bonded to surface 181 of conductive bonding layer 180 when surface 192a is a planarized surface. Hence, in some embodiments, surfaces 181 and 192a are both planarized surfaces. In some embodiments, one or both of surfaces 181 and 192a are planarized surfaces. In this way, bonding interface 182 can be positioned proximate to a planarized surface of conductive bonding layer 180 and a planarized surface of device substrate 192.

It should also be noted that donor structure 190 can be bonded to conductive bonding layer 180 without using alignment marks, which are typically used to align one substrate with another when both substrates include electronic devices. Aligning the electronic devices of one substrate with the electronic devices of another substrate a complicated, time-consuming and expensive process, so it is desirable to avoid it. As mentioned above, device substrate 192 does not include electronic devices when bonding interface is formed, so the alignment process is less complicated, less time-consuming and less expensive.

It should also be noted that bonding interface 182 is a semiconductor-to-metal bonding interface when conductive bonding layer 180 includes a metal material and device substrate 192 includes a semiconductor material. More information about bonding can be found in the above-identified related applications.

Bonding interface 182 is typically formed by providing heat to device substrate 192 and/or conductive bonding layer 180, as discussed in more detail in the above above-identified related applications. The heat is provided to device substrate 192 and/or conductive bonding layer 180 by driving their temperature to be between about 350° C. to about 600° C., although temperatures outside of this range can be used. For example, in some embodiments, the heat is provided to device substrate 192 and/or conductive bonding layer 180 by driving their temperature to be between about 300° C. to about 500° C. In one particular example, the heat is provided to device substrate 192 and/or conductive bonding layer 180 by driving their temperature to be between about 375° C. to about 425° C.

The heat provided to device substrate 192 and/or conductive bonding layer 180 to form bonding interface 182 is not provided to an electronic device included with device substrate 192 because, as discussed in more detail above, device substrate 192 does not include an electronic device before it is bonded to conductive bonding layer 180. This is useful because the heat provided to device substrate 192 and/or conductive bonding layer 180 can damage an electronic device included with device substrate 192.

In one embodiment, device substrate 192 does not include any electronic devices before it is coupled to support substrate 121 through interconnect region 150 and before bonding interface 182 is formed. In some embodiments, device substrate 192 consists essentially of a semiconductor material before it is coupled to support substrate 121 and before bonding interface 182 is formed. In some embodiments, device substrate 192 consists of a semiconductor material before it is coupled to support substrate 121 and before bonding interface 182 is formed.

In FIG. 12b, support substrate 191 is decoupled from support substrate 121. Support substrate 191 can be decoupled from support substrate 121 in many different ways. In this embodiment, support substrate 191 is decoupled from support substrate 121 by detaching support substrate 191 from device substrate 192. Support substrate 191 can be detached from device substrate 192 in many different ways. More information regarding how to detach support substrate 191 from device substrate 192 is provided in the above-identified related applications.

Support substrate 191 can be detached from device substrate 192 in many different ways. In some embodiments, support substrate 191 is detached from device substrate 192 by etching through support substrate 191 to detach region 194. support substrate 191 can be etched in many different ways, such as by using wet and dry etching. Wet etching involves etching with chemicals, and dry etching involves mechanical etching such as polishing and CMP.

In some embodiments, support substrate 191 is detached from device substrate 192 by etching detach region 194. Detach region 194 is etched when the material of detach region 194 has different etching properties than the material of support substrate 191 and device substrate 192. For example, in some embodiments, detach region 194 includes porous silicon and support substrate 191 and device substrate 192 include silicon, wherein porous silicon can be etched at a faster rate than silicon. In this way, support substrate 191 is detached from device substrate 192 by etching detach region 194.

In some embodiments, support substrate 191 is detached from device substrate 192 by applying a mechanical force to detach region 194 to cleave it. Detach region 194 is cleaved when the material of detach region 194 has different mechanical properties than the material of support substrate 191 and device substrate 192. For example, in some embodiments, detach region 194 includes porous silicon and support substrate 191 and device substrate 192 include silicon, wherein porous silicon has a weaker mechanical strength than silicon. In this way, support substrate 191 is detached from device substrate 192 by applying a mechanical force to detach region 194.

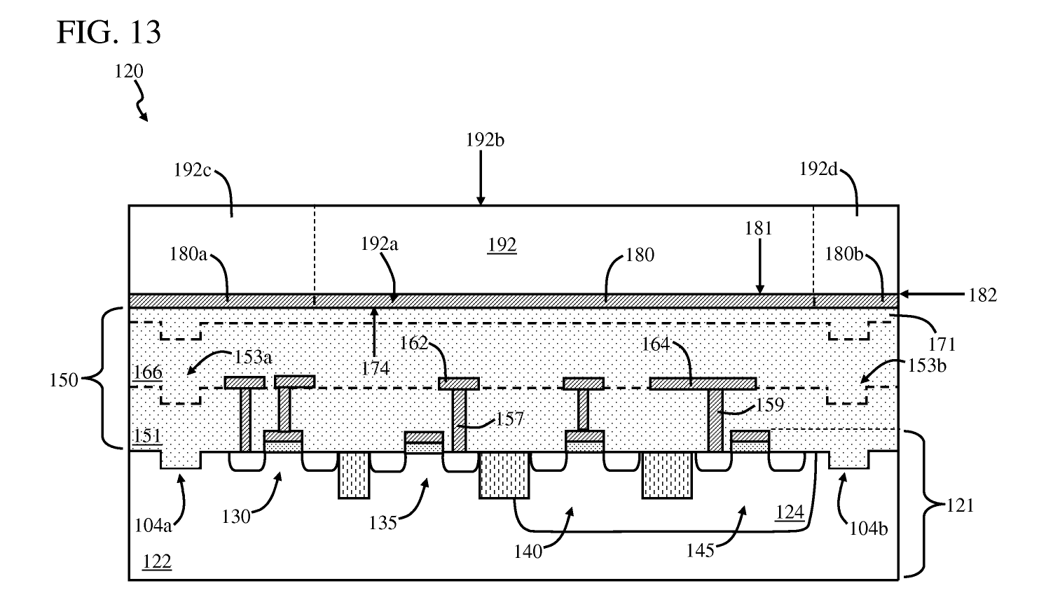

It should be noted that detach region 194 is typically removed from device substrate 192 when support substrate 191 is decoupled from support substrate 121. For example, in some situations, portions 194a and 194b are carried by device substrate 192 and support substrate 191, respectively, in response to decoupling support substrate 191 from support substrate 121. A surface 192b of device substrate 192 can be exposed, as shown in FIG. 13, in response to removing detach region 194a from device substrate 192. Surface 192b is spaced from bonding interface 182 by device substrate 192 and surface 192a is positioned towards conductive bonding layer 180. In some embodiments, surface 192b is processed after support substrate 191 is decoupled from support substrate 121. Surface 192b can be processed in many different ways, such as by etching surface 192b to remove the material of detach region 194 therefrom. Surface 192b can also be processed to remove defects and/or contaminants therefrom. Surface 192b can also be etched to make it more planar. Surface 192b can be etched in many different ways, such as by using wet and dry etching. Wet etching involves using chemicals and dry etching involves using grinding and polishing, such as chemical mechanical polishing.

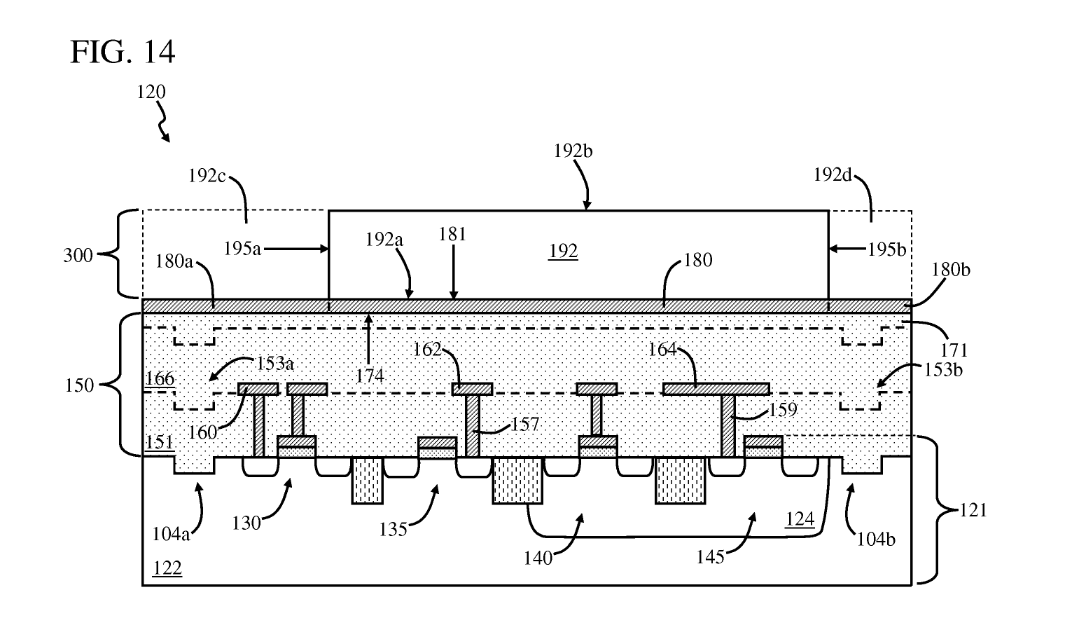

In FIGS. 13 and 14, a portion 192c of device substrate 192 as shown in FIG. 13 is removed from device substrate 192 to expose a portion of conductive bonding layer 180, denoted as portion 180a. It should be noted that a sidewall 195a is formed in response to removing portion 192c of device substrate 192. In this embodiment, sidewall 195a extends upwardly from conductive bonding layer 180. It should be noted that, in this embodiment, portions 192c is proximate to scribe lines 104a, 153a and 173a.

In FIGS. 13 and 14, a portion 192d of device substrate 192 is removed from device substrate 192 to expose a portion of conductive bonding layer 180, denoted as portion 180b. It should be noted that a sidewall 195b is formed in response to removing portion 192d of device substrate 192. In this embodiment, sidewall 195b extends upwardly from conductive bonding layer 180. It should be noted that, in this embodiment, portions 192d is proximate to scribe lines 104b, 153b and 173b.

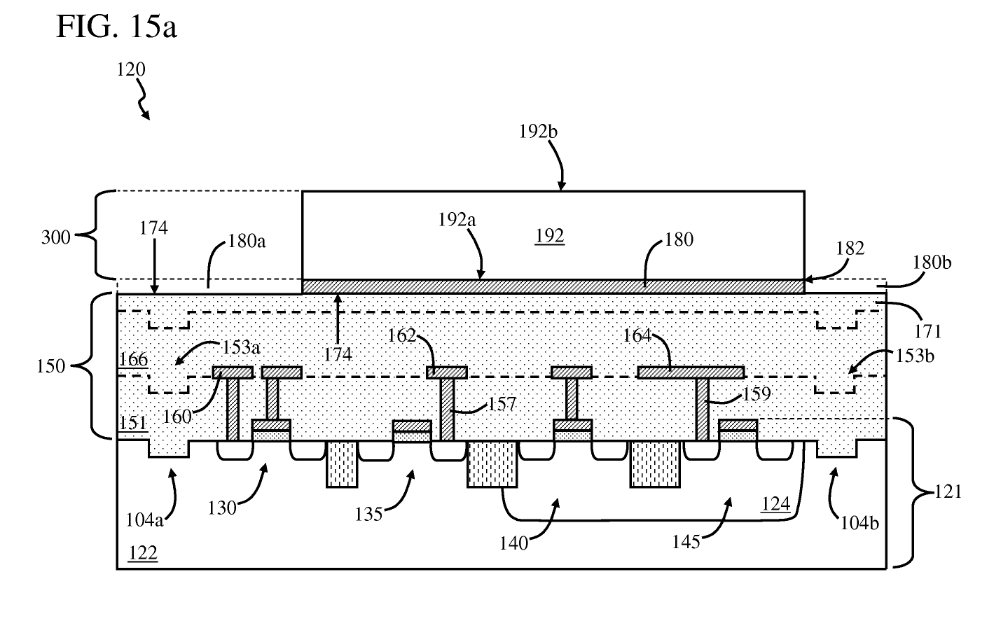

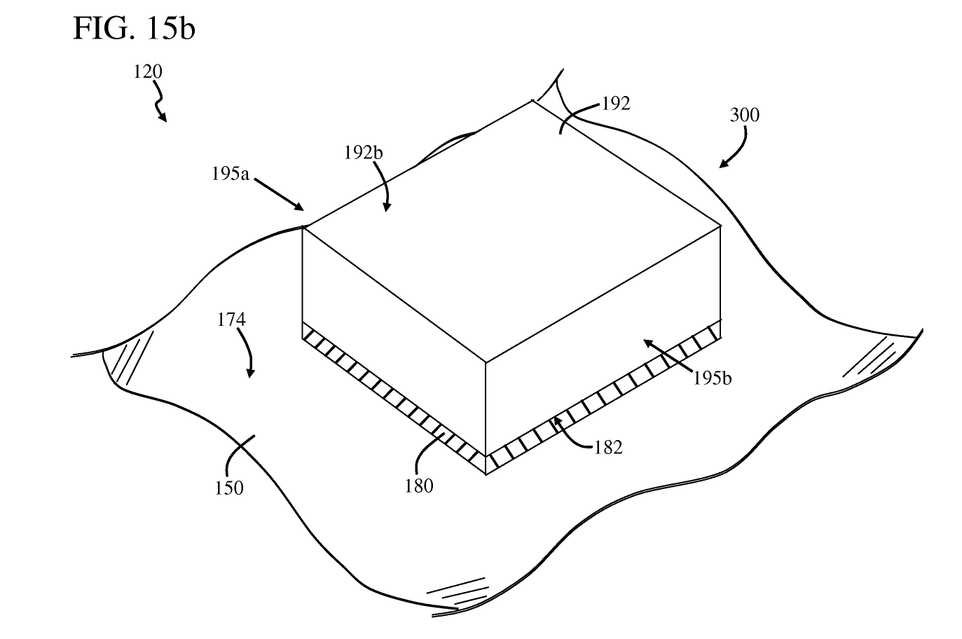

In FIGS. 14 and 15a, a portion 180a of conductive bonding layer 180 is removed from conductive bonding layer 180 to expose surface 174a of interconnect region 150. It should be noted that, in this embodiment, portions 180a and 192c are proximate to conductive contact 160 so that a connection can be made to source 131, as will be discussed in more detail below. Further, portions 180a and 192c are proximate to scribe lines 104a, 153a and 173a to reduce the amount of dishing experienced by support substrate body 122 in response to cutting through scribe lines 104a, 153a and 173a and support substrate body 122.

In FIGS. 14 and 15a, a portion 180b of conductive bonding layer 180 is removed from conductive bonding layer 180 to expose another portion of surface 174a of interconnect region 150. It should be noted that, in this embodiment, portions 180b and 192d are proximate to scribe lines 104b, 153b and 173b to reduce the amount of dishing experienced by support substrate body 122 in response to cutting through scribe lines 104b, 153b and 173b and support substrate body 122.

FIG. 15b is a perspective view of semiconductor circuit structure 120 of FIG. 15a. In this embodiment, conductive bonding layer 180 extends through a rectangular volume. However, conductive bonding layer 180 can extend through volumes having other shapes, such as cylindrical. Further, device substrate 192 extends through a rectangular volume. However, device substrate 192 can extend through volumes having other shapes, such as cylindrical.

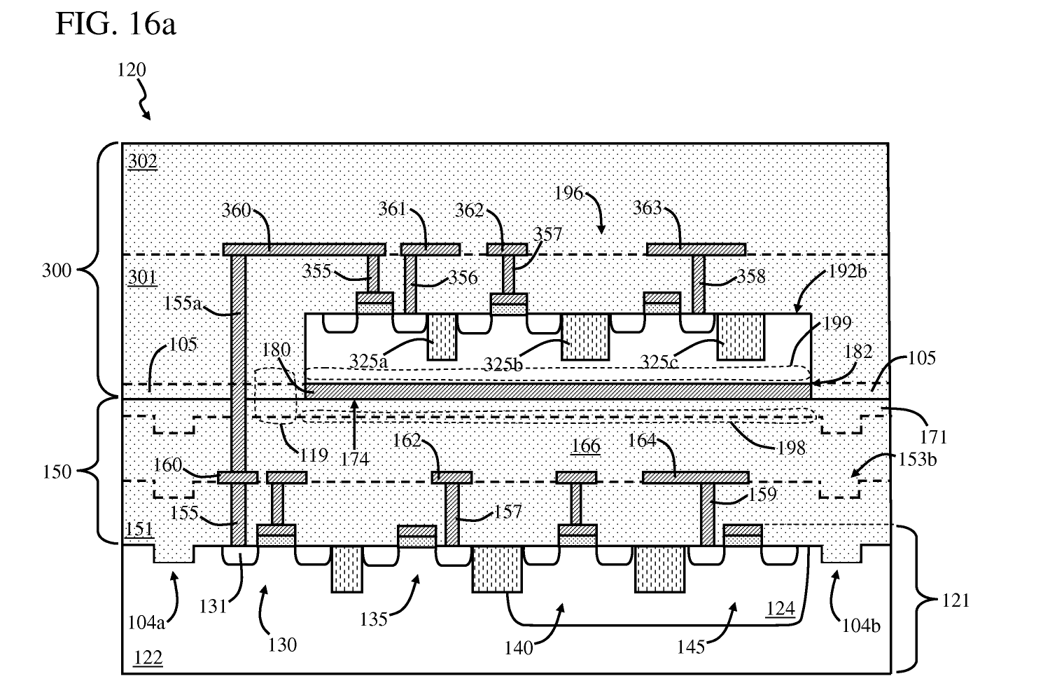

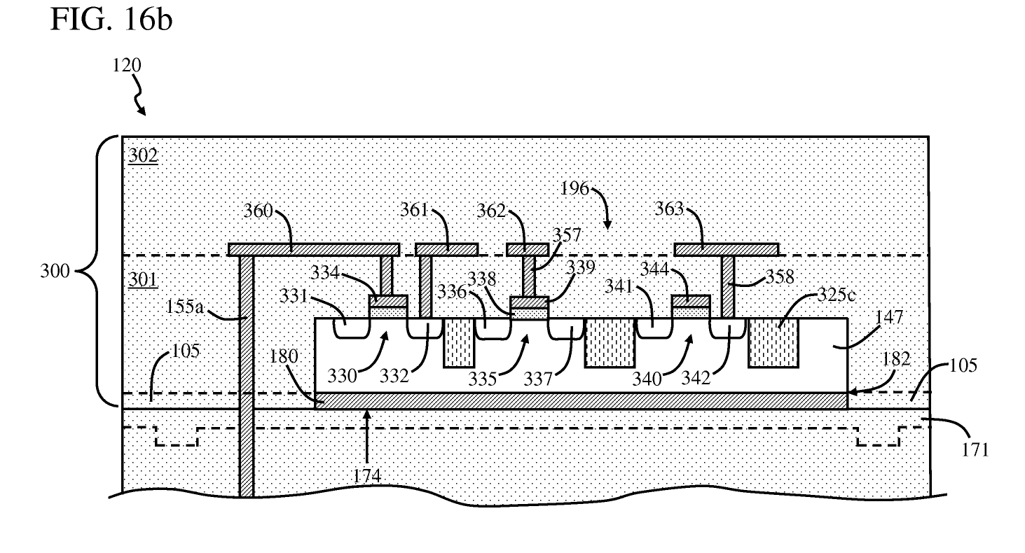

In FIGS. 16a and 16b, electronic circuitry 196 is formed so that it is carried by device substrate 192. In particular, electronic circuitry 196 is formed proximate to surface 192b. Electronic circuitry 196 can include many different types of devices, such as the passive and active devices mentioned above. Electronic circuitry 196 can include the same type of circuitry included with electronic circuitry 129. For example, electronic circuitry 196 can include CMOS circuitry having NMOS and PMOS devices. In this embodiment, electronic circuitry 196 includes laterally oriented semiconductor devices, such as lateral transistors 330, 335 and 340 (FIG. 16b). In this embodiment, lateral transistors 330, 335 and 340 are the same or similar to lateral transistors 130, 135, 140 and 145, which are discussed in more detail above.

In this embodiment, device substrate 192 carries a transistor 330, which includes a source 331 and drain 332, which extend through device substrate 192. Source 331 and drain 332 have a different doping type than device substrate 192. Transistor 330 includes a control dielectric 333 positioned on surface 192b, wherein control dielectric 333 extends between source 331 and drain 332. Transistor 330 includes a control terminal 334 positioned on control dielectric 333.

In operation, the conductivity of device substrate 192 between source 331 and drain 332 is adjustable in response to adjusting a control signal provided to control terminal 334. In this way, transistor 330 operates as a MOSFET.

In this embodiment, device substrate 192 carries a transistor 335, which includes a source 336 and drain 337, which extend through device substrate 192. Source 336 and drain 337 have a different doping type than device substrate 192. Transistor 335 includes a control dielectric 338 positioned on surface 192b, wherein control dielectric 338 extends between source 336 and drain 337. Transistor 335 includes a control terminal 339 positioned on control dielectric 338.

In operation, the conductivity of device substrate 192 between source 336 and drain 337 is adjustable in response to adjusting a control signal provided to control terminal 339. In this way, transistor 335 operates as a MOSFET.

It should be noted that device substrate 192 includes an isolation region 325a which extends between transistors 330 and 335. Isolation region 325a provides isolation between transistors 330 and 335. For example, isolation region 325a restricts the ability of current to flow between drain region 332 and source region 336 through support device substrate 192.

In this embodiment, device substrate 192 carries a transistor 340, which includes a source 341 and drain 342, which extend through device substrate 192. Source 341 and drain 342 have a different doping type than device substrate 192. Transistor 340 includes a control dielectric 343 positioned on surface 192b, wherein control dielectric 343 extends between source 341 and drain 342. Transistor 340 includes a control terminal 344 positioned on control dielectric 343.

In operation, the conductivity of device substrate 192 between source 341 and drain 342 is adjustable in response to adjusting a control signal provided to control terminal 344. In this way, transistor 340 operates as a MOSFET.

It should be noted that device substrate 192 includes an isolation region 325b which extends between transistors 335 and 340. Isolation region 325b provides isolation between transistors 335 and 340. For example, isolation region 325b restricts the ability of current to flow between drain region 337 and source region 341 through support device substrate 192. In this embodiment, device substrate 192 includes an isolation region 325c proximate to drain 342.

It should be noted that device substrate 192 includes a semiconductor material region 199 (FIG. 16a) positioned between electronic circuitry 196 and conductive bonding layer 180. In particular, semiconductor material region 199 extends between electronic circuitry 196 and conductive bonding layer 180 to provide electrical isolation therebetween. Semiconductor material region 199 is positioned between and extends between electronic circuitry 196 and bonding interface 182. Further, semiconductor material region 199 is positioned between and extends between electronic circuitry 196 and interconnect region 150.

In this embodiment, electronic circuitry 196 is formed after bonding interface 182 is formed. Forming electronic circuitry 196 after bonding interface 182 is formed is useful so that they are not exposed to the heat used to form bonding interface 182. As mentioned above, the heat used to form bonding interface 182 can damage any electronic devices included with device substrate 192. It should be noted that electronic circuitry 196 is typically formed with device substrate 192 using semiconductor device processing techniques that are well-known. These semiconductor device processing techniques generally involve doping, photolithography, masking and etching. The dopants are typically introduced using diffusion doping and ion implantation. These processing steps are typically done at a lower temperature to reduce the likelihood of electronic circuitry 129 being damaged. It should be noted that interconnect region 150 operates as a thermal barrier to heat flowing between electronic circuitry 129 and 196. The heat can be from many different sources, such as heat from the formation if electronic circuitry 196. The heat can also be from the operation of electric circuitry 196.

In FIGS. 16a and 16b, an interconnect region 300 is formed proximate to surface 174 and sidewalls 195a and 195b (FIG. 15a) of device substrate 192 of FIGS. 15a and 15b. In this embodiment, interconnect region 300 includes a dielectric material region 301 positioned so it extends upwardly from surface 174 and along sidewalls 195a and 195b. Dielectric material region 301 can include many different dielectric materials, such as those discussed in more detail above. The dielectric material included in dielectric material region 301 is typically the same dielectric material included in dielectric material regions 151, 166 and 177.

In this embodiment, interconnect region 300 includes an interconnect connected to electronic circuitry 196. The interconnect provides an interconnection between electronic circuitry 129 and 196. Electronic circuitry 129 and 196 are connected together through interconnect regions 150 and 300 so that signals can flow between them. The signals can include many different types of signals, such as data signals and control signals.

In this embodiment, interconnect region 300 includes a conductive via 155a which extends through dielectric material region 301 and interconnect region 150. Conductive view 155a is connected to source 131 through conductive contact 160 and conductive via 155.

In this embodiment, interconnect region 300 includes a conductive contact 360 positioned on dielectric material region 301 and connected to conductive via 155a. In this embodiment, interconnect region 300 includes a conductive via 355 connected to control terminal 334 and conductive contact 360. In this way, transistors 130 and 330 are in communication with each other through an interconnect which extends through interconnect regions 150 and 300.

In this embodiment, interconnect region 300 includes a conductive contact 361 positioned on dielectric material region 301, and a conductive via 356 (FIG. 16a) connected to drain 332 and conductive contact 361. In this embodiment, interconnect region 300 includes a conductive contact 362 positioned on dielectric material region 301, and a conductive via 357 connected to control terminal 339 and conductive contact 362. In this embodiment, interconnect region 300 includes a conductive contact 363 positioned on dielectric material region 301, and a conductive via 358 connected to drain 342 and conductive contact 363. It should be noted that one or more of conductive contacts 361, 362 and 363 can be connected to electronic circuitry 129, but this is not shown for simplicity.

It should also be noted that semiconductor circuit structure 120 includes a dielectric material region 119 which extends between device substrate 192 and conductive via 155a. In this embodiment, dielectric material region 119 extends between bonding interface 182 and conductive via 155a. Further, dielectric material region 119 extends between conductive bonding layer 180 and conductive via 155a. Dielectric material region 119 extends between sidewall 195a and conductive via 155a. Dielectric material region 119 extends between sidewall 195a and scribe line 173a (FIG. 9).

Dielectric material region 119 can include a portion of interconnect region 150. Dielectric material region 119 can include a portion of dielectric material region 300. In particular, dielectric material region 119 can include a portion of dielectric material regions 171 and 300.

It should also be noted that semiconductor circuit structure 120 includes a dielectric material region 198 which provides electrical isolation between electronic circuitry 129 and interconnect region 300. Further, dielectric material region 198 provides electrical isolation between the interconnects of interconnect region 150 and conductive bonding layer 180.

In this embodiment, dielectric material region 198 extends between conductive bonding layer 180 and electronic circuitry 129. Dielectric material region 198 extends between conductive bonding layer 180 and the interconnects of interconnect region 150. For example, dielectric material region 198 extends between conductive bonding layer 180 and conductive contact 162. Further, dielectric material region 198 extends between conductive bonding layer 180 and conductive via 157. In this embodiment, dielectric material region 198 extends between bonding interface 182 and electronic circuitry 129. Further, dielectric material region 199 extends between electronic circuitry 129 and electronic circuitry 196. Dielectric material region 199 extends between device substrate 192 and electronic circuitry 129. In particular, dielectric material region 199 extends between surface 192a of device substrate 192 and electronic circuitry 129. Dielectric material region 198 includes a portion of interconnect region 150. Dielectric material region 198 can include portions of dielectric material regions 166 and/or 171.

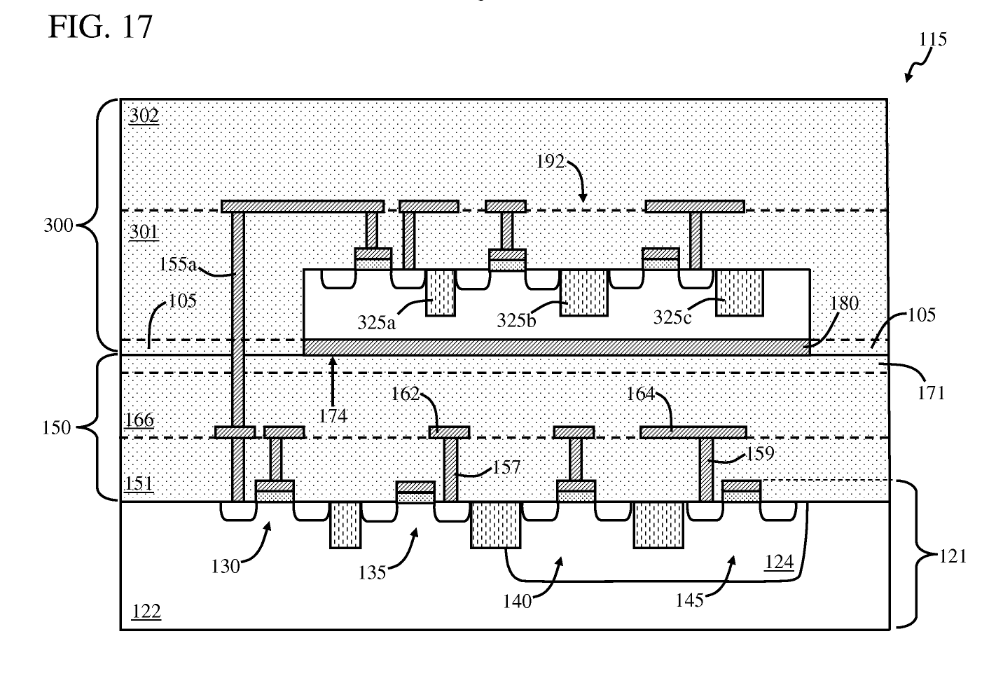

FIG. 17 is a cut-away side view of semiconductor circuit structure 120 of FIGS. 16a and 16b, wherein support substrate body 122 has been cut through in response to cutting through scribe lines 104a, 153a and 173a, as well as through scribe lines 104b, 153b and 173b, to form a die 115. It should be noted that die 115 can be the same or similar to die 101, wherein die 101 is discussed in more detail above with FIGS. 5a, 5b, 5c and 5d.

As discussed in more detail above, scribe lines 104a, 153a and 173a are aligned to reduce the amount of bowing experienced by semiconductor circuit structure 120 in response to cutting through support substrate body 122. Further, scribe lines 104b, 153b and 173b are aligned to reduce the amount of bowing experienced by semiconductor circuit structure 120 in response to cutting through support substrate body 122. In this way, the interconnects between electronic circuitry 129 and 196 are less likely to become disconnected from each other.

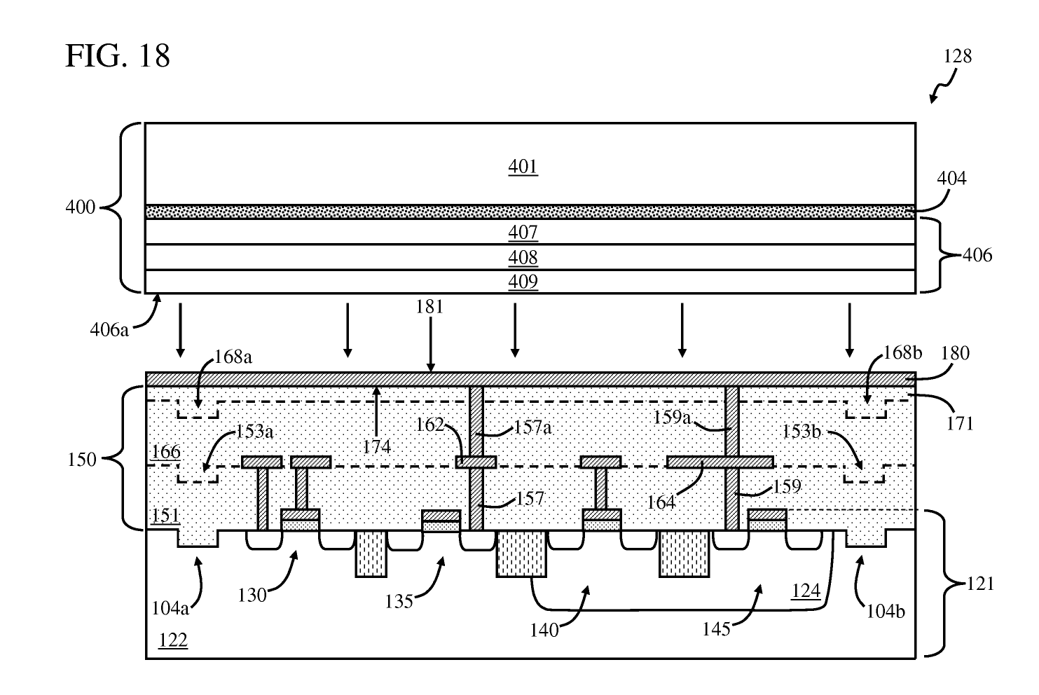

FIG. 18 is a cut-away side view of a semiconductor circuit structure 128 which can be processed to form vertically oriented semiconductor devices connected to electronic circuitry 129. In this embodiment, semiconductor circuit structure 128 includes interconnect region 150 carried by support substrate 121, and conductive bonding layer 180 carried by interconnect region 150, as shown in FIG. 11.

In FIG. 18, a donor structure 400 is provided and positioned proximate to semiconductor circuit structure 128 of FIG. 18. In some embodiments, donor structure 400 is a wafer. In some embodiments, donor structure 400 is a wafer which does not include die. In some embodiments, donor structure 400 has a major surface that is the same size as a major surface of support substrate 121. For example, in some embodiments, donor structure 400 and support substrate 121 are both twelve inch wafers.

In this embodiment, donor structure 400 includes a support substrate 401 which carries a detach region 404 and device layer structure 406. In some embodiments, detach region 194 and device layer structure 406 are blanket layers of material. More information regarding device layer structure 406 and detach region 404 can be found in the above-identified U.S. patent and patent applications, such as U.S. patent application Ser. No. 11/092,501. Detach region 404 extends between support substrate 401 and device layer structure 406 so that device layer structure 406 can be separated from support substrate 401, as will be discussed in more detail below. Detach region 404 can include many different types of materials, such as those discussed in more detail above with detach region 194.

It should be noted that device layer structure 406 can include many different types of materials, but it generally includes a semiconductor material. The semiconductor material can be of many different types, such as silicon. The semiconductor material is typically crystalline semiconductor material and is formed to have desirable electrical properties. Single crystalline semiconductor material can have localized defects, but it is generally of better material quality than amorphous or polycrystalline semiconductor material.

Device layer structure 406 can include one or more semiconductor layers, but here it is shown as including three semiconductor layers for simplicity, wherein the semiconductor layers are denoted as semiconductor layers 407, 408 and 409. In this embodiment, semiconductor layer 407 is positioned adjacent to detach layer 404, semiconductor layer 407 is positioned adjacent to semiconductor layer 407 and semiconductor layer 407 is positioned adjacent to semiconductor layer 408. Semiconductor layer 408 is positioned between semiconductor layers 407 and 409. In this way, semiconductor layers 407, 408 and 409 form a semiconductor layer stack.

In one embodiment, device layer structure 406 of FIG. 18 consists essentially of crystalline semiconductor material. In another embodiment, device layer structure 406 of FIG. 18 consists of crystalline semiconductor material. It should be noted that in these embodiments, device layer structure 406 can include defects, such as impurities, as well as dopants to provide it with a desired conductivity type.

It should also be noted that device layer structure 406 is typically doped so it has a desired doping concentration. In some embodiments, device layer structure 406 is doped so that its doping concentration is uniform between a surface 406a and detach region 404, wherein device layer structure 406 extends between surface 406a and detach region 404. It should be noted that surface 406a is a surface of semiconductor layer 409. Hence, semiconductor layer 409 includes a planarized surface when surface 406a is planarized. Surface 406a can be planarized in many different ways, such as by using wet and dry etching.

In another embodiment, device layer structure 406 is doped so that its doping concentration is non-uniform between surface 406a and device layer structure 406. In these embodiments, the doping concentration of device layer structure 406 can be less proximate to surface 406a and more proximate to detach region 404. Further, in these embodiments, the doping concentration of device layer structure 406 can be more proximate to surface 406a and less proximate to detach region 404, as discussed in more detail in U.S. patent application Ser. No. 12/040,642.

It should be noted that device layer structure 406, as shown in FIG. 18, does not carry an electronic device before it is coupled to support substrate 401, as will be discussed in more detail below. For example, in FIG. 18, device layer structure 406 does not include a horizontal transistor, and device layer structure 406 does not include a vertical transistor. In this way, device layer structure 406 consists essentially of a semiconductor material before it is coupled to support substrate 401. In some embodiments, device layer structure 406 consists of a semiconductor material before it is coupled to support substrate 401.

Device layer structure 406 can be doped in many different ways. For example, in some embodiments, semiconductor layers 407, 408 and 409 are doped n-type, p-type and n-type, respectively, so that an np junction is established between semiconductor layers 407 and 408, and a pn junction is established between semiconductor layers 408 and 409. Semiconductor layers 407, 408 and 409 are doped n-type, p-type and n-type, respectively, when it is desirable to form an NMOS transistor with 407, 408 and 409.

In some embodiments, semiconductor layers 407, 408 and 409 are doped p-type, n-type and p-type, respectively, so that a pn junction is established between semiconductor layers 407 and 408, and an np junction is established between semiconductor layers 408 and 409. Semiconductor layers 407, 408 and 409 are doped p-type, n-type and p-type, respectively, when it is desirable to form a PMOS transistor with 407, 408 and 409.

Support substrate 400 can include many different types of materials. The semiconductor material of support substrate 400 typically includes crystalline semiconductor material. In this embodiment, support substrate 400 and device layer structure 406 include crystalline semiconductor material. In particular, in this embodiment, support substrate 400 and device layer structure 406 include crystalline silicon. In other embodiments, support substrate 400 and device layer structure 406 include other types of semiconductor material, such as silicon-germanium, silicon carbide, gallium nitride, gallium arsenide, and alloys thereof. In some embodiments, support substrate 400 includes a glass material and device layer structure 406 includes a semiconductor material.

In some embodiments, the semiconductor material of device layer structure 406 includes crystalline semiconductor material. In some embodiments, the semiconductor material of device layer structure 406 consists of crystalline semiconductor material. In some embodiments, the semiconductor material of device layer structure 406 consists essentially of crystalline semiconductor material.

In some embodiments, the semiconductor material of device layer structure 406 includes silicon. In some embodiments, the semiconductor material of device layer structure 406 consists of silicon. In some embodiments, the semiconductor material of device layer structure 406 consists essentially of silicon. In any of these embodiments, the silicon can include crystalline silicon.

In some embodiments, the semiconductor material of device layer structure 406 includes silicon-germanium. In some embodiments, the semiconductor material of device layer structure 406 consists of silicon-germanium. In some embodiments, the semiconductor material of device layer structure 406 consists essentially of silicon-germanium. In any of these embodiments, the silicon-germanium can include crystalline silicon-germanium.

In some embodiments, the semiconductor material of device layer structure 406 includes silicon carbide. In some embodiments, the semiconductor material of device layer structure 406 consists of silicon carbide. In some embodiments, the semiconductor material of device layer structure 406 consists essentially of silicon carbide. In any of these embodiments, the silicon carbide can include crystalline silicon carbide.

In some embodiments, the semiconductor material of device layer structure 406 includes gallium nitride. In some embodiments, the semiconductor material of device layer structure 406 consists of gallium nitride. In some embodiments, the semiconductor material of device layer structure 406 consists essentially of gallium nitride. In any of these embodiments, the gallium nitride can include crystalline gallium nitride.

In some embodiments, the semiconductor material of device layer structure 406 includes gallium arsenide. In some embodiments, the semiconductor material of device layer structure 406 consists of gallium arsenide. In some embodiments, the semiconductor material of device layer structure 406 consists essentially of gallium arsenide. In any of these embodiments, the gallium arsenide can include crystalline gallium arsenide.

It should be noted that device layer structure 406 typically includes silicon material when it is desired to form a memory device. However, device layer structure 406 can include other types of semiconductor materials, such as those mentioned above, if it is desired to form other types of device, such as high power and high frequency transistors, as well as optical devices, such as semiconductor lasers, light emitting diodes and photosensors.

It should also be noted that, in some embodiments, device layer structure 406 includes a single layer of semiconductor material with stacked differently doped semiconductor regions and, in other embodiments, device layer structure 406 includes a plurality of differently doped semiconductor layers. In embodiments wherein device layer structure 406 includes a single layer of semiconductor material with stacked differently doped semiconductor layers, the stacked differently doped semiconductor regions are formed using ion implantation. In embodiments wherein device layer structure 406 includes a plurality of differently doped semiconductor layers, the differently doped semiconductor layers are doped during growth, although they can be doped using ion implantation, if desired.

It should also be noted that device layer structure 406 can include doped regions that are uniformly doped and doped regions that are non-uniformly doped. More information regarding doped regions that are uniformly doped and non-uniformly doped can be found in U.S. Pat. No. 7,470,598, the contents of which are incorporated herein by reference as though fully set forth herein.

Detach region 404 can include many different types of material. In one embodiment, the material of detach region 404 has a lower mechanical strength than the material of support substrate 401 and device layer structure 406. In another embodiment, the material of detach region 404 has a higher etch rate than the material of support substrate 401 and device layer structure 406.

Examples of material that can be included with detach region 404 include porous silicon. Porous silicon can be formed in many different ways. One way of forming porous silicon is disclosed in U.S. Pat. No. 6,380,099. Porous silicon includes a number of pores extending therethrough, which reduces its mechanical strength compared to crystalline silicon. Further, porous silicon includes a number of pores extending therethrough, which increases its etch rate compared to crystalline silicon. Other examples of material that can be included with detach region 404 include an oxide material, nitride material, organic bonding material, or a strained layer formed by semiconductor layers having different lattice constants. One example of semiconductor layers having different lattice constants is silicon-germanium.

In some embodiments, detach region 404 can include one or more implanted species, such as hydrogen, wherein the lattice structure of the material of detach region 404 is damaged in response to receiving the implanted species. One technique for forming detach region 404 with an implanted species is disclosed in U.S. Pat. No. 5,374,564.

It should be noted that the material of detach region 404, and its method of formation, typically depends on the material of device layer structure 406. For example, detach region 404 can include an alloy of gallium nitride when device layer structure 406 includes gallium nitride. In one particular example, support substrate 401 includes sapphire or silicon carbide and detach region 404 includes a material typically used as a buffer layer to form gallium nitride on sapphire and silicon carbide substrates. Buffer layers used to form gallium nitride on sapphire and silicon carbide substrates include III-V nitride semiconductor material, such as indium gallium nitride and aluminum gallium nitride.

It should be noted that, in the embodiments wherein device layer structure 406 includes gallium nitride, the method of manufacturing semiconductor circuit structure 128 can include a step of using laser ablation to decouple support substrate 401 from device layer structure 406. More information regarding laser ablation can be found in U.S. Pat. Nos. 6,413,839, 6,849,524 and 6,902,990.

Detach region 404 can include an alloy of gallium arsenide when device layer structure 406 includes gallium arsenide. Detach region 404 can include an alloy of a III-V compound semiconductor material when device layer structure 406 includes gallium arsenide.

Detach region 404 can include an alloy of silicon carbide when device layer structure 406 includes silicon carbide. In one particular example, detach region 404 includes a polytype of silicon carbide and device layer structure 406 includes a different polytype of silicon carbide.

As mentioned above, in some embodiments, the material of detach region 404 is easier to etch than the material of device layer structure 406. In some embodiments, the material of detach region 404 has a lower mechanical strength than the material of device layer structure 406.

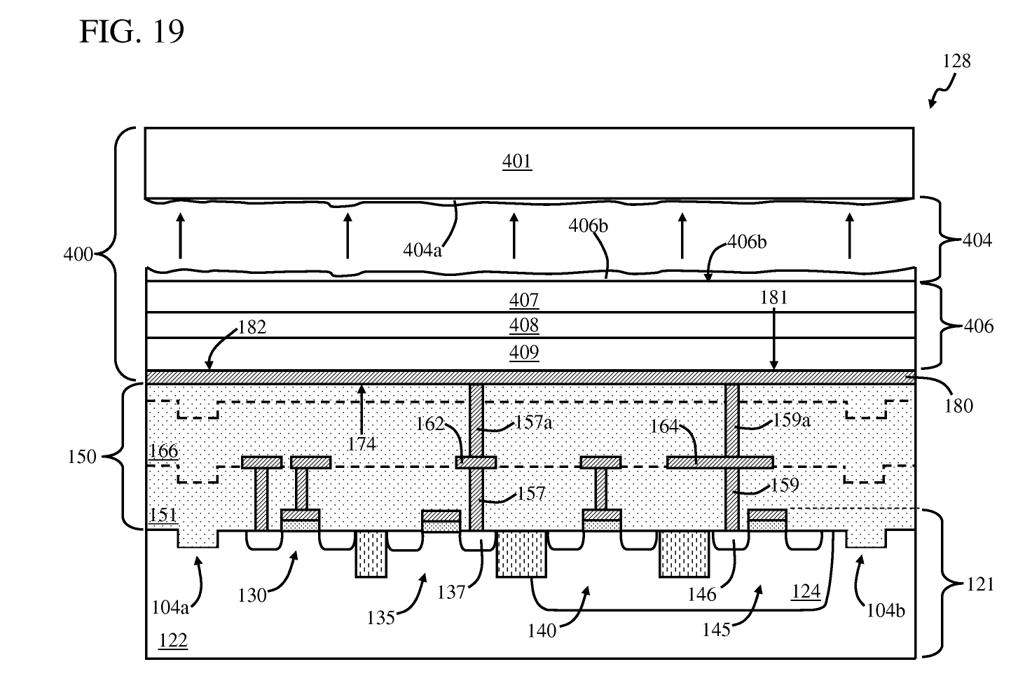

In FIG. 18, donor structure 400 is aligned with support substrate 121 and moved towards interconnect region 150 so that device layer structure 406 is bonded to conductive bonding layer 180, and bonding interface 182 is formed therebetween, as shown in FIG. 19. In particular, surface 406a of device layer structure 406 is moved towards conductive bonding layer 180 so that bonding interface 182 is formed between device layer structure 406 and conductive bonding layer 180. Semiconductor layer 409 is moved towards conductive bonding layer 180 so that bonding interface 182 is formed between semiconductor layer 409 and conductive bonding layer 180. The bonding can be accomplished in many different ways, such as those disclosed in U.S. Pat. No. 7,470,142, the contents of which are incorporated herein by reference as though fully set forth herein.

It should be noted that bonding interface 182 is formed using wafer-to-wafer alignment, which does not require a precise alignment between support substrate 400 and support substrate 121. Hence, the alignment between support substrate 400 and support substrate 121 can be accomplished faster using less expensive equipment. Being able to align support substrate 400 and support substrate 121 faster increases the throughput when manufacturing a number of bonded semiconductor structure SRAM circuits.

In FIG. 18, support substrate 400 is coupled to support substrate 121 through bonding interface 182. Further, support substrate 400 is coupled to interconnect region 150 through bonding interface 182. Device layer structure 406 is coupled to support substrate 121 through bonding interface 182. Further, device layer structure 406 is coupled to interconnect region 150 through bonding interface 182. Detach region 404 is coupled to support substrate 121 through bonding interface 182. Further, detach region 404 is coupled to interconnect region 150 through bonding interface 182.

As mentioned above, a bonding interface is an interface that is formed in response to bonding material layers together. In one example of forming a bonding interface, first and second material layers are formed as separate layers, and moved towards each other so they engage each other and the bonding interface is formed in response. In this way, a bonding interface is established. It should be noted that heat is generally applied to the first and/or second material layers to facilitate the formation of the bonding interface. In a metal-to-metal bonding interface, the first and second material layers that are bonded together are conductive materials, such as metals. In a metal-to-dielectric bonding interface, one of the first and second material layers is a conductive material, and the other one is a dielectric material. In a metal-to-semiconductor bonding interface, one of the first and second material layers is a conductive material, and the other one is a semiconductor material.

As mentioned above, a growth interface is an interface that is formed in response to growing a material layer on another material layer. In one example of forming a growth interface, a third material layer is formed, and a fourth material layer is grown on the third material layer so that the growth interface is formed in response. In this way, a growth interface is established. The fourth material layer can be grown on the third material layer in many different ways, such as by chemical vapor deposition and sputtering. Hence, when forming a growth interface, third and fourth material layers are not formed as separate layers, and moved to engage each other.

In a metal-to-metal growth interface, the third and fourth material layers are conductive materials, such as metals. In a metal-to-dielectric growth interface, one of the third and fourth material layers is a conductive material, and the other one is a dielectric material. In a metal-to-semiconductor growth interface, one of the third and fourth material layers is a conductive material, and the other one is a semiconductor material. In a dielectric-to-dielectric growth interface the third and fourth materials are dielectric materials.

It should be noted that, in general, it is difficult to establish a metal-to-semiconductor growth interface, wherein the semiconductor material is grown on the metal layer. Further, it is difficult to grow a crystalline semiconductor material layer on a metal layer using semiconductor growth techniques, such as chemical vapor deposition. In most instances, the metal layer is formed on the semiconductor material. It is difficult to grow semiconductor material on a metal layer because metal layers do not operate as a very good seed layer for the semiconductor material. Hence, a significant amount of the semiconductor material will not agglomerate on the metal layer.

It is difficult to grow crystalline semiconductor material on the metal layer because metal layers tend to not be crystalline, and semiconductor material tends to have the crystal structure of the material it is formed on. Hence, if a semiconductor material is formed on a metal layer that includes non-crystalline conductive material, then the semiconductor material will also have a non-crystalline crystal structure and poor material quality. Thus, it is useful to bond crystalline semiconductor material to a metal layer to form a metal-to-semiconductor bonding interface.

In general, bonding and growth interfaces have different types and amounts of defects. For example, dislocations often extend from a growth interface in the direction of material growth. The difference between bonding and growth interfaces can be determined in many different ways, such as by using Transmission Electron Microscopy (TEM) to determine the type and amount of defects proximate to the interface. Information regarding TEM can be found in U.S. Pat. Nos. 5,892,225, 6,531,697, 6,822,233 and 7,002,152.

More information regarding bonding and growth interfaces can be found in related U.S. patent application Ser. No. 11/606,523, the contents of which are incorporated herein by reference as though fully set forth herein. Information regarding bonding and growth interfaces can also be found in U.S. Pat. Nos. 5,152,857, 5,695,557, 5,980,633 and 6,534,382.

In FIG. 19, support substrate 401 is decoupled from device layer structure 406 by separating support substrate 401 from device layer structure 406. Support substrate 401 can be separated from device layer structure 406 in many different ways, several of which are discussed in more detail above with semiconductor circuit structure 128. In one embodiment, support substrate 401 is separated from device layer structure 406 by etching through detach region 404. Hence, support substrate 401 is decoupled from support substrate 121 and interconnect region 150 in response to etching through detach region 404. Support substrate 401 is decoupled from device layer structure 406 so that support substrate 401 is not coupled to support substrate 121 and interconnect region 150 through bonding interface 182. Support substrate 401 is decoupled from device layer structure 406 so that device layer structure 406 is carried by support substrate 121 and interconnect region 150. Support substrate 401 is decoupled from device layer structure 406 so that device layer structure 406 is coupled to support substrate 121 and interconnect region 150 through bonding interface 182, and device layer structure 406 is not coupled to support substrate 401 through detach region 404.

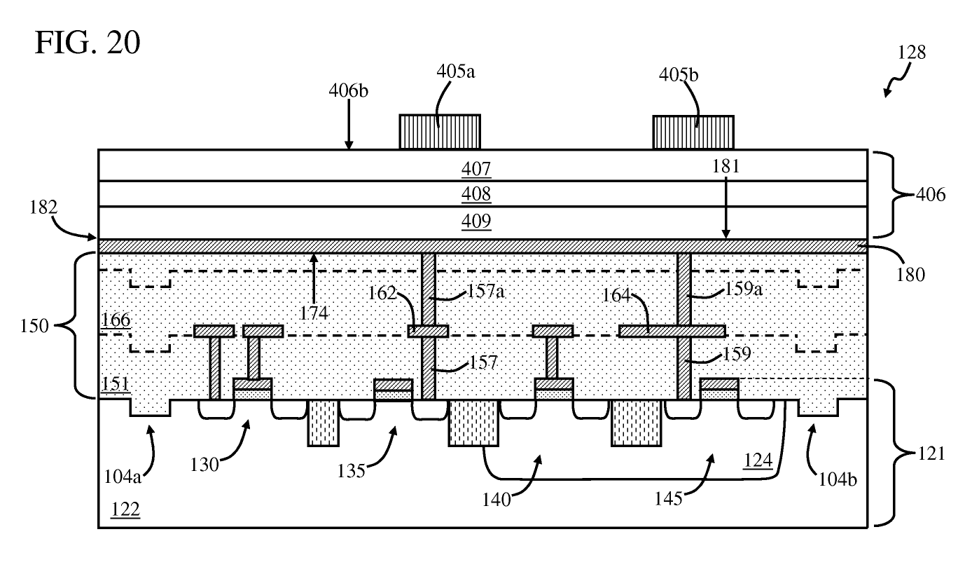

Detach region 404 can be etched in many different ways, such as by using chemical etching. It should be noted that support substrate 401 can be decoupled from device layer structure 406 in many other ways, such as by forming a crack through detach region 404. The crack can be formed through detach region 404 in many different ways, such as by applying a mechanical force. Support substrate 401 is decoupled from device layer structure 406 so that a surface 406b of device layer structure 406 is exposed, as shown in FIG. 20, wherein surface 406b is opposed to surface 406a and bonding interface 182. In some situations, surface 406b is polished to remove detach region portion 404b therefrom. Surface 406a can also be polished to remove defects therefrom. Surface 406a can be polished to adjust the thickness of device layer structure 406. Surface 406a can be polished to adjust the thickness of semiconductor layer 407.

In another embodiment, support substrate 401 is separated from device layer structure 406 by forming one or more cracks through detach region 404. Hence, support substrate 401 is decoupled from support substrate 121 and interconnect region 150 in response to cracking through detach region 404. Detach region 404 can be cracked in many different ways, such as by applying a mechanical force thereto.

It should be noted that, in FIGS. 18 and 19, electronic circuitry 129 includes laterally oriented transistors carried by support substrate 121, wherein the laterally oriented transistors are in communication with each other through conductive bonding layer 180. For example, in FIGS. 18 and 19, transistors 135 and 145 are in communication with each other through vias 157, 157a, contact 162, conductive bonding layer 180, vias 159a, 159 and contact 164. In particular, drain 137 is in communication with source 146 through vias 157, 157a, contact 162, conductive bonding layer 180, vias 159a, 159 and contact 164. In this way, semiconductor circuit structure 128 includes, in a step of the method of manufacturing, laterally oriented transistors in communication with each other through a conductive bonding layer.

In FIG. 20, a mask is formed on surface 406b, wherein the mask is patterned to allow a portion of device layer structure 406 to be removed. The mask can be of many different types, such as one that is used in photolithography. In this embodiment, the mask includes photoresist regions 405a and 405b, which are formed on surface 406b and spaced apart from each other. Photoresist regions 405a and 405b are positioned so they are above vias 157a and 159a, respectively, for reasons which are discussed in more detail below. Photoresist regions 405a and 405b include photoresist material that is more resistant to etching than the semiconductor material of device layer structure 406. Photoresist regions 405a and 405b include photoresist material that is more resistant to etching than the material of conductive bonding layer 180. Photoresist regions 405a and 405b can be formed in many different ways, such as by using standard photoresist deposition, patterning and photolithography techniques.

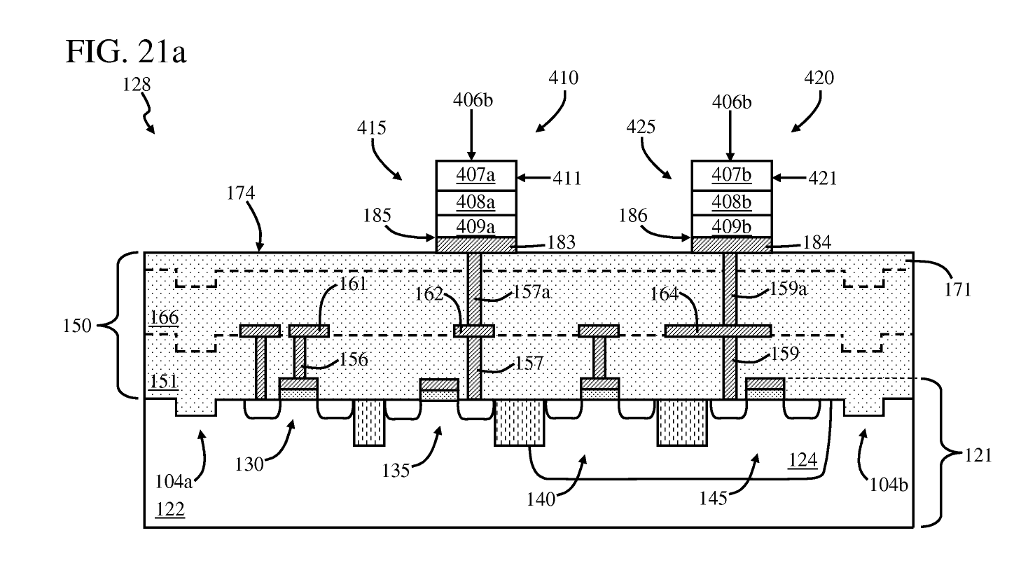

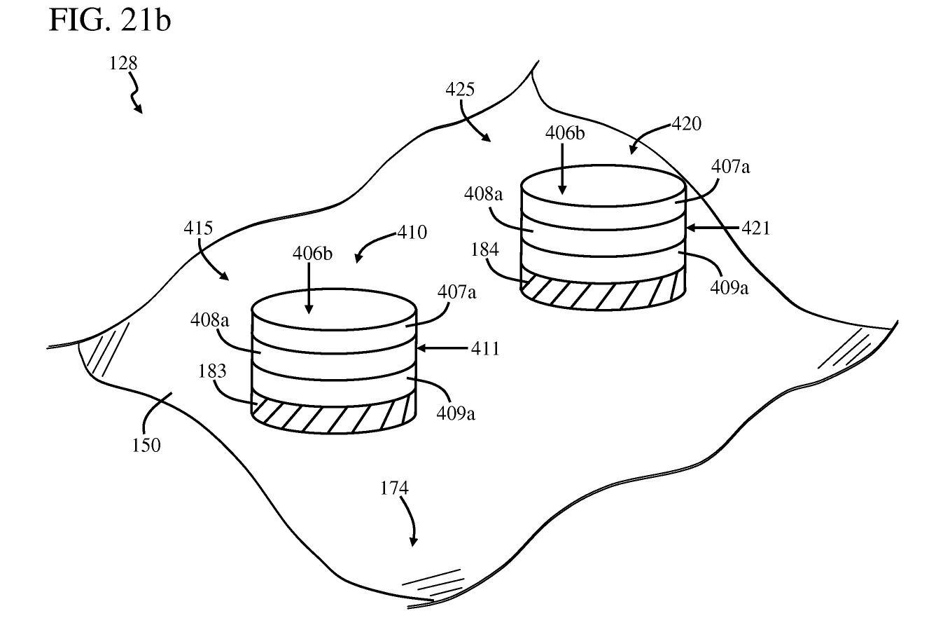

In FIG. 21a, device layer structure 406 is etched to remove portions thereof away from photoresist regions 405a and 405b to form mesa structures 415 and 425, respectively. In FIGS. 21a and 21b, photoresist regions 405a and 405b have been removed from mesa structures 415 and 425. It should be noted that vertically oriented semiconductor devices 410 and 420 will be fabricated, wherein vertically oriented semiconductor devices 410 and 420 include mesa structures 415 and 425, respectively.

Portions of device layer structure 406 are etched to form mesa structures 415 and 425, wherein mesa structure 415 extends between surface 406b and via 157a and mesa structure 425 extends between surface 406b and via 159a. Mesa structures 415 and 425 can have many different shapes, such as rectangular. In this embodiment, mesa structures 415 and 425 are cylindrical in shape, as shown in FIG. 21b. Mesa structures 415 and 425 include sidewalls 411 and 421, respectively, which extend away from surface 174. Sidewalls 411 and 421 extend away from conductive bonding contact regions 183 and 184, respectively, which are discussed in more detail below. In this embodiment, sidewall 411 is an annular sidewall because it extends annularly around semiconductor layers 407a, 408a and 409a. Further, sidewall 421 is an annular sidewall because it extends annularly around semiconductor layers 407b, 408b and 409b. It should be noted that sidewall 411 extends around the outer periphery of semiconductor layers 407a, 408a and 409a, and sidewall 421 extends around the outer periphery of semiconductor layers 407b, 408b and 409bb.

Mesa structure 415 includes semiconductor layers 407a, 408a and 409a, wherein semiconductor layers 407a, 408a and 409a correspond to portions of device layer structure 406 between surface 406b and via 157a that have not been etched away. In particular, semiconductor layers 407a, 408a and 409a correspond to portions of semiconductor layers 407, 408 and 409, respectively, between surface 406b and via 157a that have not been etched away. More information regarding forming mesa structures can be found in U.S. patent application Ser. Nos. 11/092,500, 11/092,501 and 11/180,286, as well as U.S. Pat. Nos. 7,470,598 and 7,470,142, all of which are incorporated herein by reference as though fully set forth herein.

Semiconductor layer 408a is positioned between semiconductor layers 407a and 409a, and semiconductor layer 409a is positioned towards via 157a and semiconductor layer 407a is positioned away from via 157a. Semiconductor layers 407a and 409a operate as a source and drain, respectively, of vertically oriented transistor 410. Semiconductor layer 408a operates as a channel region with a conductivity that can be controlled in response to a control signal applied to a control terminal, as will be discussed in more detail below.

Mesa structure 425 includes semiconductor layers 407b, 408b and 409b, wherein semiconductor layers 407b, 408b and 409b correspond to portions of device layer structure 406 between surface 406b and via 159a that have not been etched away. In particular, semiconductor layers 407b, 408b and 409b correspond to portions of semiconductor layers 407, 408 and 409, respectively, between surface 406b and via 159a that have not been etched away.

Semiconductor layer 408b is positioned between semiconductor layers 407b and 409b, and semiconductor layer 409b is positioned towards 159a 170 and semiconductor layer 407b is positioned away from 159a. Semiconductor layers 407b and 409b operate as a source and drain, respectively, of vertically oriented transistor 420. Semiconductor layer 408b operates as a channel region with a conductivity that can be controlled in response to a control signal applied to a control terminal, as will be discussed in more detail below.

Further, conductive bonding layer 180 is etched to remove portions thereof away from mesa structures 415 and 425. In particular, portions of conductive bonding layer 180 are etched to leave conductive bonding contact regions 183 and 184, wherein conductive bonding contact region 183 extends between mesa structure 415 and via 157a and conductive bonding contact region 184 extends between mesa structure 425 and via 159a. Portions of conductive bonding layer 180 are etched to leave conductive bonding contact regions 183 and 184, wherein regions 183 and 184 each include a sidewall which extends away from surface 174. Conductive bonding contact regions 183 and 184 carry mesa structures 415 and 425, respectively. Conductive bonding contact regions 183 and 184 bond mesa structures 415 and 425, respectively, to interconnect region 150. Mesa structures 415 and 425 are spaced from surface 174 by conductive bonding contact regions 183 and 184, respectively.

Device layer structure 406 and conductive bonding layer 180 are etched to remove portions of bonding interface 182. In particular, portions of device layer structure 406 and conductive bonding layer 180 are etched to leave bonding interfaces 185 and 186, wherein bonding interface 185 extends between mesa structure 415 and via 157a and bonding interface 186 extends between mesa structure 425 and via 159a. Mesa structure 415 is coupled to support substrate 121 and interconnect region 150 through bonding interface 185 and mesa structure 425 is coupled to support substrate 121 and interconnect region 150 through bonding interface 186. In particular, mesa structure 415 is coupled to via 157a through bonding interface 185 and mesa structure 425 is coupled to via 159a through bonding interface 186. It should be noted that a signal that flows between mesa structure 415 and via 157a flows though bonding interface 185 and a signal that flows between mesa structure 425 and via 159a flows though bonding interface 186.

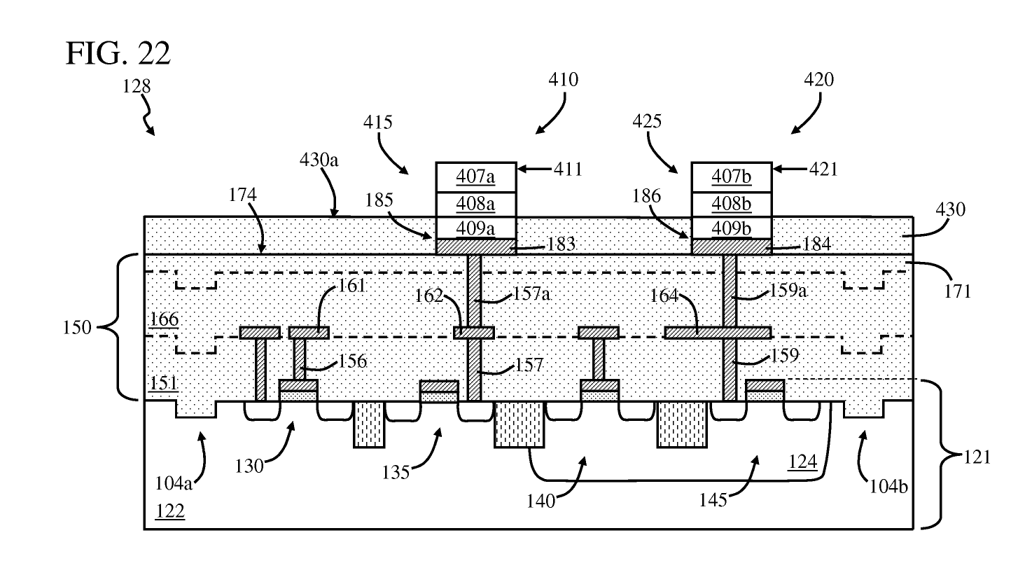

In FIG. 22, a dielectric material region 430 is formed on surface 174, wherein dielectric material region 430 covers conductive bonding contacts 183 and 184, as well as bonding interfaces 185 and 186. Further, dielectric material region 430 extends upwardly from surface 174 to cover semiconductor layers 409a and 409b. In particular, dielectric material region 430 extends upwardly from surface 174 so its exposed surface 430a is proximate to the interface between semiconductor layers 408a and 409a. In this way, semiconductor layers 407a and 408a extend upwardly from surface 430a. Further, dielectric material region 430 extends upwardly from surface 174 so its exposed surface 430a is proximate to the interface between semiconductor layers 408b and 409b. In this way, semiconductor layers 407b and 408b extend upwardly from surface 430a.

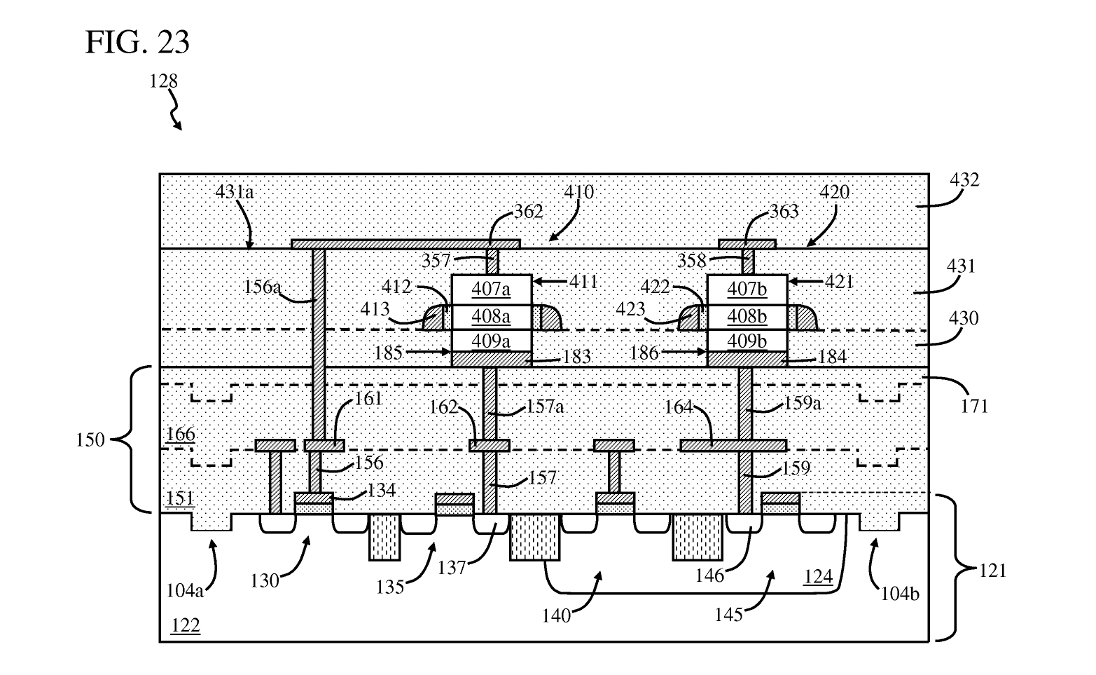

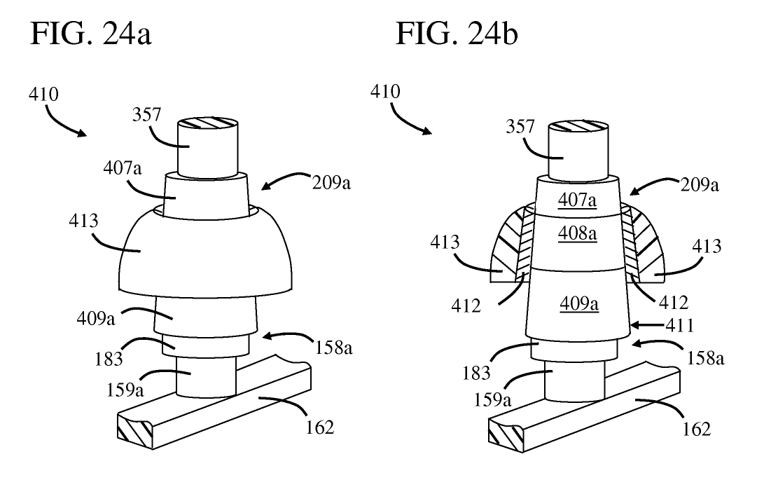

In FIG. 23, mesa structures 415 and 425 are processed to form vertically oriented transistors 410 and 420, respectively. Vertically oriented transistor 410 is shown in perspective views in FIGS. 24a and 24b.

In this embodiment, a control dielectric 412 is formed around mesa structure 415 and a control terminal 413 is formed around control dielectric 412. Control dielectric 412 and control terminal 413 are positioned around mesa structure 415 so that the conductivity of semiconductor layer 408a can be controlled in response to a control signal applied to control terminal 413. Control dielectric 412 is positioned adjacent to sidewall 411. Control dielectric 412 extends between sidewall 411 and control terminal 413.

Further, a control dielectric 422 is formed around mesa structure 425 and a control terminal 423 is formed around control dielectric 422. Control dielectric 422 and control terminal 423 are positioned around mesa structure 425 so that the conductivity of semiconductor layer 408b can be controlled in response to a control signal applied to control terminal 423. Control dielectric 422 is positioned adjacent to sidewall 421. Control dielectric 422 extends between sidewall 421 and control terminal 423.

It is useful for transistors 410 and 420 to include mesa structures so that more current can flow therethrough. For example, vertically oriented transistors have been fabricated that allow more than about three to four times more current to flow therethrough than corresponding horizontally oriented devices. Another advantage is that the current flowing through the mesa structure is more spread out so that the vertically oriented transistor heats up less in response.

It should be noted that control dielectric 412 extends annularly around mesa structure 415 and control terminal 413 extends annularly around control dielectric 412 and mesa structure 415. Further, control dielectric 422 extends annularly around mesa structure 425 and control terminal 423 extends annularly around control dielectric 422 and mesa structure 425. It is useful for transistors 410 and 420 to include control dielectrics and control terminals which extend annularly around a mesa structure so that the current flowing through the mesa structure can be better controlled.

Control terminals 413 and 423 can include many different types of conductive materials. In some embodiments, control terminals 413 and 423 include the same conductive materials as that included with the conductive lines of interconnect region 150. In other embodiments, control terminals 413 and 423 include different conductive materials than that included with the conductive lines of interconnect region 150.

Control dielectrics 412 and 422 can include many different dielectric materials. In some embodiments, control dielectrics 412 and 422 include the same dielectric materials as that included with the dielectric material region 431. In other embodiments, control dielectrics 412 and 422 include different dielectric materials than that included with dielectric material region 431. In some embodiments, control dielectrics 412 and/or 422 include a single layer of dielectric material and, in other embodiments, control dielectrics 412 and 422 include a plurality of dielectric material layers. For example, in one embodiment, control dielectrics 412 and/or 422 include an oxide-nitride-oxide layer structure. One example of an oxide-nitride-oxide layer structure is a layer structure with silicon nitride positioned between opposed silicon oxide layers.

In FIG. 23, a dielectric material region 431 is formed on mesa structures 415 and 425, as well as on control dielectrics 412 and 422 and control terminals 413 and 423. A conductive via 357 is formed so it extends through dielectric material region 431 and connects to semiconductor layer 407a and a conductive via 358 is formed so it extends through dielectric material region 431 and connects to semiconductor layer 407b.

In FIG. 23, a conductive via 156a is formed so it extends through dielectric material regions 151, 166, 171, 430 and 431, wherein via 156a is connected to control terminal 134 of transistor 130 through conductive interconnect 161 and via 156. A conductive contact 362 is formed on surface 431a of dielectric material region 431, wherein conductive contact 362 is connected to semiconductor layer 407a through conductive via 357. Conductive contact 362 is connected conductive via 156a. Control terminal 134 is connected to semiconductor layer 407a through conductive vias 156 and 156a, as well as through conductive contacts 161 and 362. In this way, devices 130 and 410 are in communication with each other.

Semiconductor layer 409a is in communication with drain region 137 through conductive vias 157 and 157a, as well as through conductive contact 162 and bonding interface 185. In this way, devices 135 and 410 are in communication with each other.

A conductive contact 363 is formed on surface 431a of dielectric material region 431, wherein conductive contact 363 is connected to semiconductor layer 407b through via 358.

Semiconductor layer 409b is in communication with source region 146 through conductive vias 159 and 159a, as well as through conductive contact 164 and bonding interface 186. In this way, devices 145 and 420 are in communication with each other.

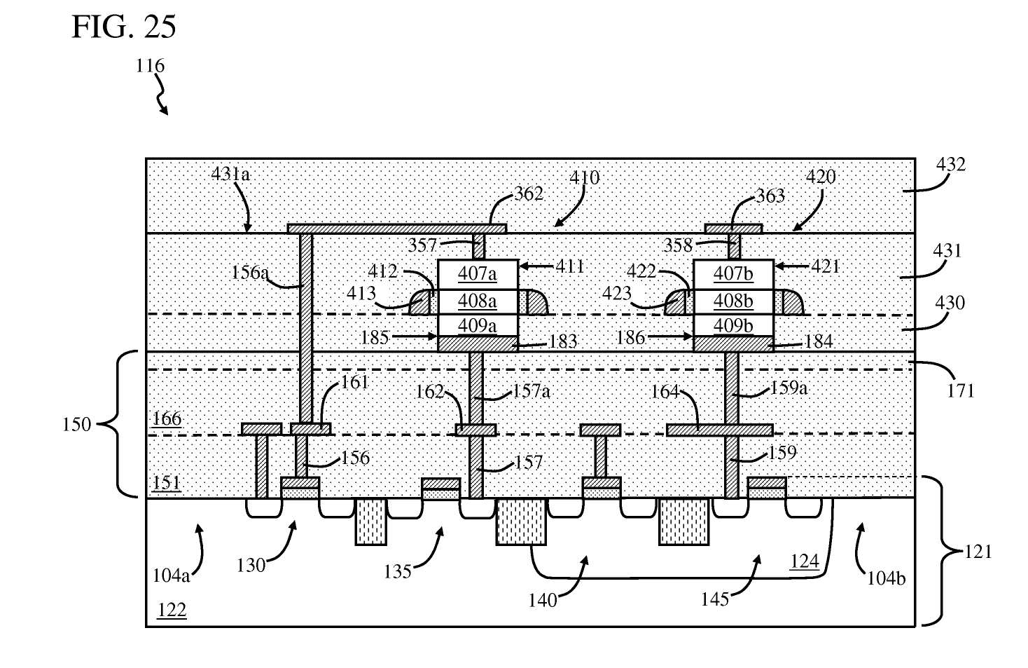

FIG. 25 is a cut-away side view of semiconductor circuit structure 128 of FIG. 23, wherein support substrate body 122 has been cut through in response to cutting through scribe lines 104a, 153a and 173a, as well as through scribe lines 104b, 153b and 173b, to form a die 116. It should be noted that die 116 can be the same or similar to die 101, wherein die 101 is discussed in more detail above with FIGS. 5a, 5b, 5c and 5d.

As discussed in more detail above, scribe lines 104a, 153a and 173a are aligned to reduce the amount of bowing experienced by semiconductor circuit structure 120 in response to cutting through support substrate body 122. Further, scribe lines 104b, 153b and 173b are aligned to reduce the amount of bowing experienced by semiconductor circuit structure 120 in response to cutting through support substrate body 122. In this way, the interconnects between electronic circuitry 129 and 196 are less likely to become disconnected from each other.

The embodiments of the invention described herein are exemplary and numerous modifications, variations and rearrangements can be readily envisioned to achieve substantially equivalent results, all of which are intended to be embraced within the spirit and scope of the invention as defined in the appended claims.

1. A method, comprising:
providing a first substrate which carries a circuit and interconnect region; and
coupling a second substrate to the interconnect region through a conductive bonding layer, wherein the second substrate includes first and second portions and a detach layer.

2. The method of claim 1, further including planarizing an exposed surface of the interconnect region.

3. The method of claim 1, wherein the coupling step includes forming the conductive bonding layer proximate to an exposed surface of the interconnect region.

4. The method of claim 1, further including removing the first portion of the second substrate so the first portion is coupled to the interconnect region through the conductive bonding layer.

5. The method of claim 4, further including planarizing an exposed surface of the second portion of the second substrate.

6. The method of claim 4, further including forming a circuit carried by the second portion of the second substrate.

7. The method of claim 6, further including forming an interconnect region carried by the second portion of the second substrate.

8. The method of claim 5, further including forming a circuit proximate to the planarized surface.

9. The method of claim 8, further including forming an interconnect region proximate to the planarized surface.

10. The method of claim 1, further including planarizing an exposed surface of the second portion of the second substrate.

11. The method of claim 10, wherein the coupling step includes forming a bonding interface proximate to the planarized surface.

12. The method of claim 1, further including removing a portion of the conductive contact region.

13. The method of claim 12, further including forming a dielectric material region in the space occupied by the portion of the conductive contact region that was removed.

14. The method of claim 12, further including forming a via which connects the first and second interconnect regions together.

15. The method of claim 14, wherein the via extends through the space occupied by the portion of the conductive contact region that was removed.

16. The method of claim 1, wherein the second portion includes a stack of semiconductor layers.

17. The method of claim 1, wherein the second portion includes a stack of crystalline semiconductor layers.

18. The method of claim 1, wherein the second portion includes a stack of single crystalline semiconductor layers.

19. The method of claim 1, wherein the second portion includes a stack of blanket layers of semiconductor material.
